(19) United States
(12) Patent Application Publication
(10) Pub. No.: US 2026/0025119 A1
(43) Pub. Date: Jan. 22, 2026

(54) Lamb Wave Resonator and Preparation Method Thereof, Filter, Radio Frequency Module, and Electronic Device

(71) Applicant: Huawei Technologies Co., Ltd., Shenzhen (CN)

(72) Inventors: Xiang Tao, Shanghai (CN); Xin Jiang, Shenzhen (CN); Daiping Tang, Shanghai (CN); Jian Gu, Shanghai (CN); Han Ke, Shanghai (CN); Zhongzhi Luan, Shenzhen (CN)

(21) Appl. No.: 18/994,970

(22) PCT Filed: Aug. 11, 2023
(86) PCT No.: PCT/CN2023/112727

§ 371 Date: Jan. 15, 2025

(30) Foreign Application Priority Data
Aug. 27, 2022 (CN) 202211036177.8

(51) Int. Cl. H03H 9/02; H03H 3/02; H04B 1/40

(52) U.S. Cl. CPC H03H 9/02228; H03H 3/02; H04B 1/40

(57) ABSTRACT

A filter comprises a lamb wave resonator that includes a substrate, a piezoelectric layer, an interdigital transducer, and a dielectric layer. The piezoelectric layer is disposed on the substrate, and the interdigital transducer and the dielectric layer are disposed on a side of the piezoelectric layer that is distal from the substrate. The interdigital transducer includes a plurality of first electrode fingers and a plurality of second electrode fingers that are alternately arranged in sequence in a first direction. The first direction intersects extension directions of the first and the second electrode fingers. The dielectric layer includes a first part, and the first part is disposed on a surface of the piezoelectric layer and is located on a periphery of the first electrode fingers and the second electrode fingers.

This application claims priority to Chinese Patent Application No. 202211036177.8, filed with the China National Intellectual Property Administration on Aug. 27, 2022 and entitled “LAMB WAVE RESONATOR AND PREPARATION METHOD THEREOF, FILTER, RADIO FREQUENCY MODULE, AND ELECTRONIC DEVICE”, which is incorporated herein by reference in its entirety.

### TECHNICAL FIELD

This application relates to the field of radio frequency technologies, and in particular, to a lamb wave resonator and a preparation method thereof, a filter, a radio frequency module, and an electronic device.

### BACKGROUND

With explosive growth of mobile data, the communication industry has advanced to the 5th generation mobile communication technology (5th generation mobile communication technology, 5G), which requires a radio frequency front-end resonator to have a higher frequency, a wider bandwidth, and a stronger power tolerance. Currently, there are mainly two types of radio frequency front-end resonators: a surface acoustic wave (surface acoustic wave, SAW) resonator and a bulk acoustic wave (bulk acoustic wave, BAW) resonator. A frequency of the SAW resonator is lower than 3.5 GHZ, and an electromechanical coupling coefficient of the SAW resonator is only about 10%. An electromechanical coupling coefficient of the BAW resonator is also small. However, a lamb wave (lamb wave) resonator has become a research hotspot in recent years because of a high sound velocity, a large electromechanical coupling coefficient (up to 25%), and other advantages.

Therefore, how to obtain a high-performance lamb wave resonator becomes a technical problem that needs to be resolved urgently.

### SUMMARY

Embodiments of this application provide a lamb wave resonator and a preparation method thereof, a filter, a radio frequency module, and an electronic device, to provide a high-performance lamb wave resonator.

To achieve the foregoing objective, the following technical solutions are used in this application.

According to a first aspect of embodiments of this application, a lamb lamb wave resonator is provided. As an element of a filter, the lamb lamb wave resonator may be used in a radio frequency device. The lamb wave resonator includes a substrate, a piezoelectric layer, an interdigital transducer, and a dielectric laver. The piezoelectric layer is disposed on the substrate, and the interdigital transducer and the dielectric layer are disposed on a side that is of the piezoelectric layer and that is away from the substrate. The interdigital transducer includes a plurality of first electrode fingers and a plurality of second electrode fingers. The plurality of first electrode fingers and the plurality of second electrode fingers are alternately arranged in a first direction. The first direction intersects extension directions of the first electrode fingers and the second electrode fingers. The dielectric layer includes a first part, and the first part is disposed on a surface of the piezoelectric layer and is located on a periphery of the first electrode fingers and the second electrode fingers. In other words, the first part is located at a gap of the interdigital transducer. For example, the dielectric layer may be used as a frequency shift layer, a temperature compensation layer, or a passivation layer at the same time.

In the lamb wave resonator provided in this embodiment of this application, a thickness S2 of a second part that is of the dielectric layer and that is located above the interdigital transducer is thinned, so that plate wave spurious modes such as a lateral higher-order harmonic of an A0 mode and a lateral higher-order harmonic of an S0 mode in the lamb wave resonator can be suppressed, flatness in a passband can be improved, a loss can be reduced, and performance of the lamb wave resonator can be improved. In addition, in the lamb wave resonator provided in this embodiment of this application, thinning the thickness of the second part that is of the dielectric layer and that is located above the interdigital transducer is equivalent to processing the dielectric layer. Compared with processing a piezoelectric layer in a conventional technology, a preparation process of the lamb wave resonator provided in this embodiment of this application is simple, and has a low process difficulty and a large process tolerance, so that a yield rate of the lamb wave resonator can be improved. In addition, it is found through simulation that the lamb wave resonator provided in this embodiment of this application has a good suppression effect on the plate wave spurious modes such as the lateral higher-order harmonic of the A0 mode and the lateral higher-order harmonic of the S0 mode. In addition, for a filter that is used in a 5G frequency band like an n77 frequency band, an n78 frequency band, or an n79 frequency band and whose operating frequency is in a sub-6G frequency band, the lamb wave resonator usually includes a frequency shift layer or a passivation layer whose material is a dielectric material. Therefore, the frequency shift layer or the passivation layer may be directly used as the dielectric layer in the lamb wave resonator provided in this embodiment of this application, where only the frequency shift layer or the passivation layer needs to be processed. and no new film layer needs to be added, so that the lamb wave resonator is slightly modified.

In some possible implementations, the dielectric layer further includes the second part. the second part is located on a top surface of the interdigital transducer, a thickness of the first part is S1, a thickness of the second part is S2, and S1>S2. A dielectric layer with a thin thickness may alternatively be disposed above the interdigital transducer, and when thicknesses of the piezoelectric layer and an interdigital electrode layer in the lamb wave resonator are different, the second part may be thinned to suppress the lateral higher-order harmonic of the A0 mode and the lateral higher-order harmonic of the S0 mode in different lamb wave resonators.

In some possible implementations, S1−S2≤50 nm. A difference between the thickness of the first part and the thickness of the second part is limited to being greater than 50 nm, so that the lateral higher-order harmonic of the A0 mode and the lateral higher-order harmonic of the S0 mode can be well suppressed.

In some possible implementations, the thickness of the first part is S1, and 20 nm≤S1≤200 nm. A value of the thickness of the first part of the dielectric layer is limited to 20 nm to 200 nm, so that the lateral higher-order harmonic of the A0 mode and the lateral higher-order harmonic of the S0 mode can be suppressed while a thickness of the lamb wave resonator is not excessively increased.

In some possible implementations. S1−S2≤65 nm, and 110 nm≤S1≤140 nm. The thickness difference between the first part and the second part is limited to being greater than 65 nm, and the value of the thickness of the first part is limited to 110 nm to 140 nm, so that the lateral higher-order harmonic of the A0 mode and the lateral higher-order harmonic of the S0 mode can almost be completely suppressed, and the performance of the lamb wave resonator is good.

In some possible implementations, a value range of a thickness of the interdigital transducer is 60 nm to 140 nm. In the lamb wave resonator provided in this embodiment of this application, the value range of the thickness of the interdigital transducer is wide, so that the lamb wave resonator may be used in scenarios that have different requirements on the thickness of the interdigital transducer, and an application scope is wide.

In some possible implementations, a top surface of the first part is flush with a top surface of the second part. This is a possible structure.

In some possible implementations, a top surface of the first part is higher than a top surface of the second part. This is a possible structure.

In some possible implementations, a top surface of the first part is lower than a top surface of the second part. This is a possible structure.

In some possible implementations. the second part has a first projection on the piezoelectric layer, the interdigital transducer has a second projection on the piezoelectric layer, and the second projection includes the first projection. The second part is aligned with the interdigital transducer in terms of structure, so that the suppression effect on the lateral higher-order harmonic of the A0 mode and the lateral higher-order harmonic of the S0 mode is good.

In some possible implementations, the lamb wave resonator further includes a passivation layer, the passivation layer is disposed on a side that is of the dielectric layer and that is away from the piezoelectric layer, and a value range of a thickness of the passivation layer is 1 nm to 50 nm. The passivation layer is disposed, so that a film layer between the passivation layer and the substrate can be protected, so as to prolong a service life of the lamb wave resonator 100.

In some possible implementations, a material of the dielectric layer includes SiO₂, Si₃N₄, or Al₂O₃. This is a possible implementation.

In some possible implementations, the lamb wave resonator further includes an acoustic wave reflection layer, and the acoustic wave reflection layer is disposed on a side that is of the piezoelectric layer and that is away from the interdigital transducer. An acoustic wave reflection coefficient of a surface that is of the acoustic wave reflection layer and that faces the piezoelectric layer is R, and 0.5≤R≤0.86.

The acoustic wave reflection layer is disposed on the side that is of the piezoelectric layer and that is close to the substrate, and acoustic impedance of the acoustic wave reflection layer is less than acoustic impedance of the piezoelectric layer. In this way, an acoustic wave excited by the lamb wave resonator is reflected on the surface that is of the acoustic wave reflection layer and that faces the piezoelectric layer, and is reflected back to the piezoelectric laver. The single acoustic wave reflection layer is formed on the substrate, so that the acoustic wave can be locked in the piezoelectric layer, to avoid a problem that device performance is severely degraded because a large quantity of acoustic waves excited by the lamb wave resonator leak to the substrate. The acoustic wave reflection layer replaces a conventional air cavity and a Bragg reflector, and there is no need to remove a cavity or form a complex Bragg reflector. This simplifies a preparation process of the lamb wave resonator, and reduces a preparation difficulty of the lamb wave resonator. In addition, because there is no need to form an air cavity on the substrate, mechanical strength of the lamb wave resonator can be enhanced, and the yield rate of the lamb wave resonator can be improved.

In some possible implementations, 0.55≤R≤0.8. The acoustic wave reflection coefficient R is limited to 0.55 to 0.8, so that problems in material selection, thickness setting, a preparation process, and the like of the acoustic wave reflection layer can be considered while device performance is met, so as to reduce preparation costs.

In some possible implementations, a minimum thickness of the acoustic wave reflection layer is y, and y=77.75379*R²−173.22328*R+97.70404. In this embodiment of this application. a material selection range of the acoustic wave reflection layer is wide. An acoustic wave reflection coefficient R of an acoustic wave reflection layer of each material is different, and a thickness of the acoustic wave reflection layer of each material is also different In this application, the minimum thickness of the acoustic wave reflection layer is limited, so that a characteristic of the lamb wave resonator can meet a requirement, and preparation of the acoustic wave reflection layer can be facilitated, so as to balance a plurality of characteristics of the lamb wave resonator, such as performance, costs, a process, and reliability.

In some possible implementations, a thickness of the acoustic wave reflection layer ranges from 3.5 μm to 30 μm. This is a thickness range that facilitates mass production.

In a possible implementation, a material of the acoustic wave reflection Javer is a macromolecular material. In this embodiment of this application, the material selection range of the acoustic wave reflection layer is wide, and this is easy for implementation.

In a possible implementation, the material of the acoustic wave reflection layer includes polyimide. polydimethylsiloxane, polymethyl methacrylate, polyvinylidene fluoride, or polyethylene glycol terephthalate. These are some low-cost and easy-to-implement material selections. In a possible implementation, the acoustic wave reflection layer is of a single film layer

structure. The acoustic wave reflection layer with the single film layer structure is simple in structure and process.

According to a second aspect of embodiments of this application, a filter is provided, including a plurality of cascaded lamb wave resonators, where the lamb wave resonator is the lamb wave resonator according to any implementation of the first aspect.

The filter provided in the second aspect of embodiments of this application includes the lamb wave resonator in the first aspect. Beneficial effects of the filter are the same as beneficial effects of the lamb wave resonator. Details are not described herein again.

According to a third aspect of embodiments of this application, a radio frequency module is provided, including a filter and a power amplifier, where the filter is coupled to the power amplifier, and the filter is the filter in the second aspect.

The radio frequency module provided in the third aspect of embodiments of this application includes the lamb wave resonator in the first aspect. Beneficial effects of the radio frequency module are the same as beneficial effects of the lamb wave resonator. Details are not described herein again.

According to a fourth aspect of embodiments of this application, an electronic device is provided, including a filter and a circuit board, where the filter is disposed on the circuit board, and the filter is the filter in the second aspect.

The electronic device provided in the fourth aspect of embodiments of this application includes the lamb wave resonator in the first aspect. Beneficial effects of the electronic device are the same as beneficial effects of the lamb wave resonator. Details are not described herein again.

According to a fifth aspect of embodiments of this application, a preparation method of a lamb wave resonator is provided, including: forming a piezoelectric layer: forming an interdigital transducer on a side of the piezoelectric layer, where the interdigital transducer includes a plurality of first electrode fingers and a plurality of second electrode fingers, the plurality of first electrode fingers and the plurality of second electrode fingers are alternately arranged in a first direction, and the first direction intersects extension directions of the first electrode fingers and the second electrode fingers; and forming a dielectric layer on a side of the piezoelectric layer, where the dielectric layer and the interdigital transducer are located on the same side of the piezoelectric layer, the dielectric layer includes a first part, and the first part is disposed on a surface of the piezoelectric layer and is located on a periphery of the first electrode fingers and the second electrode fingers.

According to the preparation method of the lamb wave resonator provided in this embodiment of this application, the dielectric layer required in this embodiment of this application may be formed by controlling a process for forming the dielectric layer, to provide a lamb wave resonator that can suppress a lateral higher-order harmonic of an A0 mode and a lateral higher-order harmonic of an S0 mode. The process of processing the dielectric material is simple and easy to implement, and a yield rate is high.

In some possible implementations, the dielectric layer further includes a second part. the second part is located on a top surface of the interdigital transducer, and a thickness of the first part is greater than a thickness of the second part, and the forming a dielectric layer on a side of the piezoelectric layer includes: after the interdigital transducer is formed, forming a first dielectric film on a side that is of the interdigital transducer and that is away from the piezoelectric layer, where the first dielectric film covers the interdigital transducer and the piezoelectric layer; and forming a second dielectric film on the first dielectric film, where the second dielectric film is located on the periphery of the first electrode fingers and the second electrode fingers, to form the dielectric layer, the second dielectric film and a part that is of the first dielectric film and that is located on the surface of the piezoelectric layer constitute the first part, and a part that is of the first dielectric film and that is located on the top surface of the interdigital transducer is used as the second part. This is an implementation with a simple process.

In some possible implementations, the dielectric layer further includes a second part, the second part is located on a top surface of the interdigital transducer, and a thickness of the first part is greater than a thickness of the second part; and the forming a dielectric layer on a side of the piezoelectric layer includes: after the interdigital transducer is formed, forming a third dielectric film on a side that is of the interdigital transducer and that is away from the piezoelectric layer, where the third dielectric film covers the interdigital transducer and the piezoelectric layer: and thinning a part that is of the third dielectric film and that is located on the top surface of the interdigital transducer, to form the dielectric layer, where a part that is of the third dielectric film and that is located on the surface of the piezoelectric layer is used as the first part, and the thinned part of the third dielectric film is used as the second part. This is an implementation with a simple process.

In some possible implementations, the thickness of the first part is S1, the thickness of the second part is S2, and S1>S2. A dielectric layer with a thin thickness may alternatively be disposed above the interdigital transducer, and when thicknesses of the piezoelectric layer and an interdigital electrode layer in the lamb wave resonator are different, the second part may be thinned to suppress the lateral higher-order harmonic of the A0 mode and the lateral higher-order harmonic of the S0 mode in different lamb wave resonators.

In some possible implementations, S1−S2≤50 nm. A difference between the thickness of the first part and the thickness of the second part is limited to being greater than 50 nm, so that the lateral higher-order harmonic of the A0 mode and the lateral higher-order harmonic of the S0 mode can be well suppressed.

In some possible implementations, the second part has a first projection on the piezoelectric layer, the interdigital transducer has a second projection on the piezoelectric laver, and the second projection includes the first projection. The second part is aligned with the interdigital transducer in terms of structure, so that the suppression effect on the lateral higher-order harmonic of the A0 mode and the lateral higher-order harmonic of the S0 mode is good.

### BRIEF DESCRIPTION OF DRAWINGS

FIG. 1 is a diagram of a framework of an electronic device according to an embodiment of this application;

FIG. 2 is a diagram of a topology structure of a filter according to an embodiment of this application;

FIG. 3A is a diagram of a partial structure of a lamb wave resonator according to an embodiment of this application;

FIG. 3B is a diagram of a three-dimensional admittance curve of the lamb wave resonator shown in FIG. 3A according to an embodiment of this application;

FIG. 4A is a diagram of a partial structure of another lamb wave resonator according to an embodiment of this application;

FIG. 4B is a diagram of a partial structure of another lamb wave resonator according

to an embodiment of this application;

FIG. 4C is a diagram of a two-dimensional admittance curve of the lamb wave resonator shown in FIG. 4A according to an embodiment of this application;

FIG. 4D is a diagram of a two-dimensional admittance curve of the lamb wave resonator shown in FIG. 4B according to an embodiment of this application;

FIG. SA is a diagram of a structure of a lamb wave resonator according to an embodiment of this application;

FIG. 5B is a diagram of a structure of another lamb wave resonator according to an embodiment of this application;

FIG. 5C is a diagram of a structure of another lamb wave resonator according to an embodiment of this application;

FIG. 5D is a diagram of a structure of another lamb wave resonator according to an embodiment of this application;

FIG. 6A is a top view of an interdigital transducer according to an embodiment of this application;

FIG. 6B is an enlarged view at M in FIG. 5D;

FIG. 7A is a diagram of a structure of another lamb wave resonator according to an embodiment of this application;

FIG. 7B is a top view of a dielectric layer according to an embodiment of this application;

FIG. 8A is a diagram of comparison between admittance curves according to an embodiment of this application;

FIG. 8B is a diagram of an admittance curve of a lamb wave resonator according to an embodiment of this application; FIG. 9A is a diagram of a structure of another lamb wave resonator according to an

embodiment of this application;

FIG. 9B is a top view of another dielectric layer according to an embodiment of this application;

FIG. 9C is a diagram of a structure of another lamb wave resonator according to an embodiment of this application;

FIG. 10A to FIG. 10C are comparison diagrams of an admittance curve of a lamb wave resonator in a case in which a thickness of a second part changes according to an embodiment of this application;

FIG. 11A to FIG. 11C are comparison diagrams of an admittance curve of a lamb wave resonator in a case in which a thickness of an interdigital transducer changes according to an embodiment of this application;

FIG. 12 is a diagram of a structure of another lamb wave resonator according to an embodiment of this application;

FIG. 13 is a diagram of a structure of another lamb wave resonator according to an embodiment of this application;

FIG. 14 is a diagram of a preparation procedure of a lamb wave resonator according to an embodiment of this application; and

FIG. 15 is a diagram of steps of preparing a lamb wave resonator according to an embodiment of this application.

### REFERENCE NUMERALS

1: electronic device; 11: cover plate; 12: display; 13: middle frame; 131: bearing plate; 132: side frame; 14: rear housing; 10: filter; 100: lamb wave resonator; 110: piezoelectric layer; 111: release window; 120: interdigital transducer; 121a: first busbar; 122a: second busbar; 121b: first electrode finger; 122b: second electrode finger; 130: dielectric layer; 131: first part; 132: second part; 140: substrate; 141: groove; and 150: passivation layer.

### DESCRIPTION OF EMBODIMENTS

The following describes the technical solutions in embodiments of this application with reference to the accompanying drawings in embodiments of this application. It is clear that the described embodiments are merely a part rather than all of embodiments of this application.

The terms such as “first” and “second” below are only for ease of description, and cannot be construed as indicating or implying relative importance or implicitly indicating a quantity of indicated technical features. Therefore, a feature limited by “first”, “second”, or the like may explicitly or implicitly include one or more features. In the descriptions of this application, unless otherwise stated, “a plurality of” means two or more than two.

In addition, in embodiments of this application, orientation terms such as “upper”, “lower”, “left”, and “right” may include but are not limited to definitions based on illustrated orientations in which components in the accompanying drawings are placed. It should be understood that, these directional terms may be relative concepts. They are used for description and clarification of relative positions, and may vary accordingly depending on a change in the orientations in which the components in the accompanying drawings are placed in the accompanying drawings.

In embodiments of this application, unless otherwise clearly specified and limited, a term “connection” should be understood in a broad sense. For example, the “connection” may be a fixed connection, a detachable connection, or an integrated connection, or may be a direct connection or an indirect connection implemented through an intermediate medium. In addition, the term “coupling” may be a direct electrical connection, or may be an indirect electrical connection through an intermediate medium. The term “contact” may be direct contact or indirect contact through an intermediate medium.

In embodiments of this application, “and/or” describes an association relationship between associated objects, and represents that three relationships may exist. For example, A and/or B may represent the following cases: Only A exists, both A and B exist, and only B exists, where A and B may be singular or plural. The character “/” generally represents an “or” relationship between the associated objects.

An embodiment of this application provides an electronic device. The electronic device is, for example, a consumer electronic product, a home electronic product, a vehicle-mounted electronic product, a financial terminal product, or a communication electronic product. The consumer electronic product is, for example, a mobile phone (mobile phone), a tablet computer (pad), a notebook computer, an e-reader, a personal computer (personal computer, PC), a personal digital assistant (personal digital assistant, PDA), a desktop display, an intelligent wearable product (for example, a smart watch or a smart band), a virtual reality (virtual reality, VR) terminal device, an augmented reality (augmented reality, AR) terminal device, or an uncrewed aerial vehicle. The home electronic product is, for example, an intelligent lock, a television, a remote control, a refrigerator, and a small household charging appliance (for example, a soy milk maker or a robot vacuum). The vehicle-mounted electronic product is, for example, a vehicle-mounted navigator or a vehicle-mounted high-density digital video disc (digital video disc, DVD). The financial terminal product is, for example, an automated teller machine (automated teller machine, ATM), a terminal for self-service business handling, or the like. For example, the communication electronic product is a communication device like a server, a memory, a radar, or a base station.

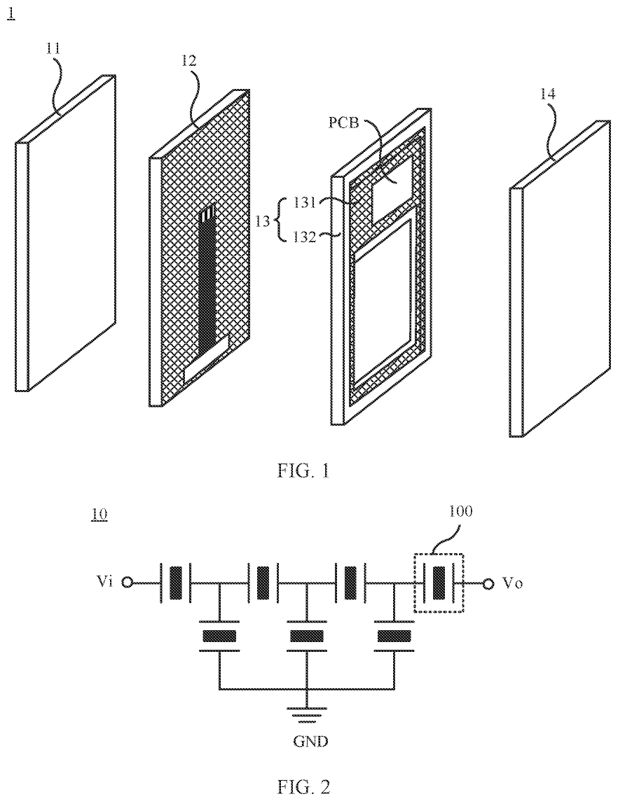

For ease of description, the following uses an example in which the electronic device is a mobile phone for description. As shown in FIG. 1, an electronic device 1 mainly includes a cover 11, a display 12, a middle frame 13, and a rear housing 14. The rear housing 14 and the display 12 are respectively located on two sides of the middle frame 13, the middle frame 13 and the display 12 are disposed in the rear housing 14, the cover 11 is disposed on a side that is of the display 12 and that is away from the middle frame 13, and a display surface of the display 12 faces the cover 11.

The display 12 may be a liquid crystal display (liquid crystal display, LCD). In this case, the liquid crystal display includes a liquid crystal display panel and a backlight module. The liquid crystal display panel is disposed between the cover 11 and the backlight module, and the backlight module is configured to provide a light source for the liquid crystal display panel. The display 12 may alternatively be an organic light-emitting diode (organic light-emitting diode, OLED) display. Because the OLED display is a self-luminous display, no backlight module needs to be disposed.

The middle frame 13 includes a bearing plate 131 and a side frame 132 surrounding the bearing plate 131. The electronic device 1 may further include electronic components such as a printed circuit board (printed circuit board, PCB), a battery, and a camera. The electronic components such as the printed circuit board, the battery, and the camera may be disposed on the bearing plate 131.

The electronic device 1 may further include a system on chip (system on chip, SOC). a radio frequency chip, and the like that are disposed on the PCB. The PCB is configured to carry the system on chip, the radio frequency chip, and the like, and is electrically connected to the system on chip, the radio frequency chip, and the like. The radio frequency chip may include parts such as a filter and a processor. The processor is configured to process various signals. The filter is an important part of radio frequency signal processing, and is configured to block a signal of another frequency through a signal of a specific frequency.

An embodiment of this application provides a filter. The filter may be used in the foregoing electronic device 1, for example, used in the radio frequency chip in the electronic device 1. The filter provided in this embodiment of this application may be, for example, a low-pass filter, a high-pass filter, a band-pass filter, a band-stop filter, or an active filter.

Certainly, the filter provided in this embodiment of this application is not limited to being integrated into the electronic device 1. Alternatively, the filter may be independently used as a component, or the filter may be integrated with a component like a power amplifier into a module (for example, a radio frequency component, a radio frequency module, or a filter module). The filter is coupled to the power amplifier to perform signal processing and transmission.

As shown in FIG. 2, an embodiment of this application provides a filter 10, including a plurality of cascaded lamb wave (lamb wave) resonators 100. The plurality of lamb (lamb) wave resonators 100 may have different resonance frequencies, and may be cascaded together in a serial-parallel manner. FIG. 2 further shows a signal input end Vi, a signal output end Vo, and a ground end GND of the filter 10.

Herein, the lamb wave resonator 100 has a high sound velocity (for example, 12000m/s to 15000 m/s), a large electromechanical coupling coefficient (for example, up to 25%), and other advantages, and is mostly used in various radio frequency terminal devices. The filter 10 formed by the lamb wave resonators 100 that are cascaded in the serial-parallel manner and have different resonance frequencies has a small passband insertion loss, high out-of-band steepness, a strong power tolerance, and other advantages.

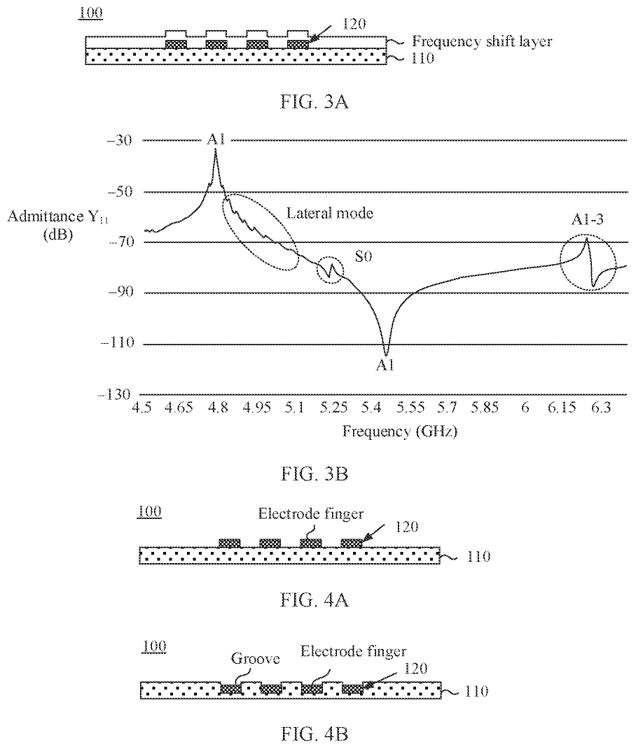

FIG. 3A shows a lamb wave resonator 100 including a piezoelectric layer 110, an interdigital transducer 120, and a frequency shift layer. FIG. 3B is a diagram of an admittance curve of the lamb wave resonator 100 shown in FIG. 3A. It is found from the diagram of the admittance curve that, in addition to a main mode, namely, a first-order antisymmetric (A1) mode.

three types of spurious modes: a lateral mode (energy leakage in an aperture direction), a lateral third-order harmonic of a first-order antisymmetric mode (A1-3), and a lateral higher-order harmonic of a zero-order antisymmetric (A0) mode and a lateral higher-order harmonic of a zero-order symmetric (S0) mode, often occur in the lamb wave resonator 100.

The lateral mode is caused by leakage of acoustic wave energy in an aperture direction of an electrode finger (an extension direction of electrode fingers in the interdigital transducer 120, or a direction perpendicular to a current section in a perspective of FIG. 3A). Acoustic waves that exceed a resonant cavity (a range of the resonant cavity defined by an electrode finger end) are referred to as leaked acoustic waves Leakage of the acoustic waves in the aperture direction forms a series of small resonance peaks between positive and negative resonance peaks of the A1 mode in the admittance diagram, as shown in a dotted box in FIG. 3B. causing fluctuation in a passband of the lamb wave resonator 100.

The A1 mode generates a higher-order harmonic laterally, and a harmonic closest to the A1 mode is an A1-3 harmonic. As shown in FIG. 3B, a location of the harmonic corresponds to a range of the passband, and usually falls within the passband of the lamb wave resonator 100, causing fluctuation in the passband of the lamb wave resonator 100.

The lateral higher-order harmonic of the S0 mode is a type of plate wave. Between the positive and negative resonance peaks of the A1 mode, the lateral higher-order harmonic of the S0 mode further occurs. As shown in FIG. 3B, this type of spurious mode is the lateral higher-order harmonic of the S0 mode. The lateral higher-order harmonic of the S0 mode also causes in-band fluctuation of the lamb wave resonator 100 and increases a loss. It should be understood that a wave propagated in the piezoelectric layer is usually referred to as a plate wave, and a wave propagated on a surface of the piezoelectric layer is usually referred to as a surface wave.

In different lamb wave resonators 100, the lateral higher-order harmonic of the S0 mode may occur, or the lateral higher-order harmonic of the A0 mode may occur. The lateral higher-order harmonic of the A0 mode is also a type of plate wave, and occurs between the positive and negative resonance peaks of the A1 mode. The lateral higher-order harmonic of the A0 mode also causes in-band fluctuation of the lamb wave resonator 100 and increases a loss. Certainly, the lateral higher-order harmonic of the A0 mode and the lateral higher-order harmonic of the S0 mode may alternatively occur at the same time, causing in-band fluctuation of the lamb wave resonator 100 and increasing a loss.

The foregoing three types of spurious modes all cause fluctuation in the passband of the lamb wave resonator 100, increase an in-band loss, and reduce performance of the lamb wave resonator 100.

The following lists embodiments in which the lateral mode and the A1-3 harmonic can be suppressed.

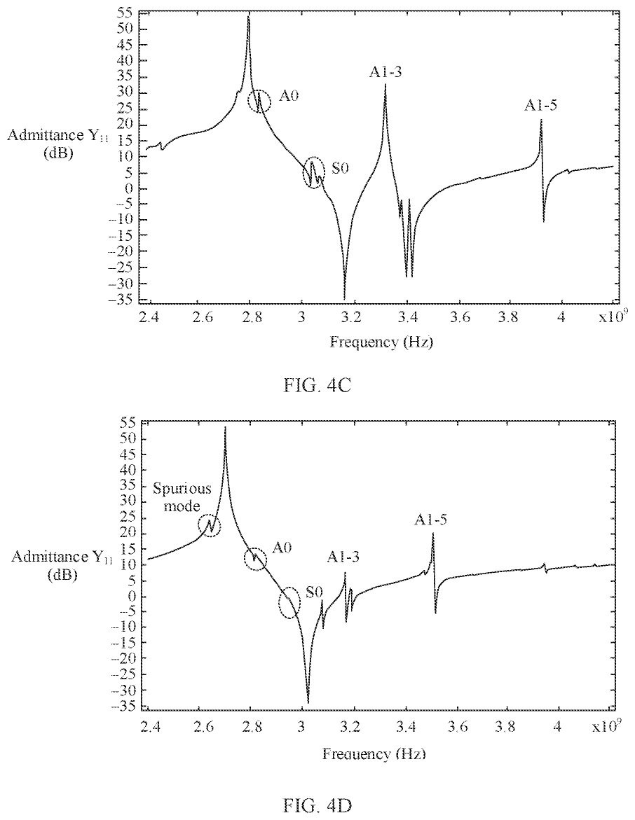

In some technologies, as shown in FIG. 4A, a conventional lamb wave resonator 100 includes a piezoelectric layer 110 and an interdigital transducer 120, and the interdigital transducer 120 is disposed on a surface of the piezoelectric layer 110. Due to coverage of electrode fingers. an area covered by the electrode fingers and an area not covered by the electrode fingers on the surface of the piezoelectric layer 110 have different structures. As a result, acoustic impedance mismatch (or understood as unequal acoustic impedance) occurs, and dispersion curves (curves generated when a resonance frequency changes with a wavelength) also mismatch, causing acoustic wave reflection and a spurious mode. As shown in FIG. 4B, a lamb wave resonator 100 is provided, including a piezoelectric

layer 110 and an interdigital transducer 120. A surface of the piezoelectric layer 110 has a groove. the interdigital transducer 120 has a plurality of electrode fingers, and the electrode fingers of the interdigital transducer 120 are disposed in the groove.

FIG. 4C is a diagram of an admittance curve of the lamb wave resonator 100 shown in FIG. 4A, and FIG. 4D is a diagram of an admittance curve of the lamb wave resonator 100 shown in FIG. 4B. It can be learned through comparison between FIG. 4C and FIG. 4D that the area covered by the electrode fingers on the piezoelectric layer 110 is etched to a specific depth, and then electrode finger deposition is performed, so that acoustic impedance of the area covered by the electrode fingers and acoustic impedance of the area not covered by the electrode fingers are adjusted to be basically consistent, and the A1-3 harmonic can be suppressed.

However, when a lower concave electrode finger structure is used to suppress the A1-3 harmonic, a groove needs to be formed on the piezoelectric layer 110. Based on particularity of a material of the piezoelectric layer 110, a preparation process of forming the groove on the piezoelectric layer 110 is complex and difficult. In addition, a suppression principle of the lower concave electrode finger structure is as follows: A groove is formed by thinning the piezoelectric layer 110, to decrease acoustic impedance in an area in which the groove is located. However, disposing an electrode finger in the groove may increase the acoustic impedance of the area in which the groove is located. Decreased acoustic resistance cooperates with increased acoustic resistance. so that the acoustic resistance in the area in which the groove is located matches (or understood as being equal to) acoustic impedance at another location (at which no electrode finger is disposed) of the piezoelectric layer 110, so as to suppress the A1-3 harmonic. Therefore, an A1-3 harmonic suppression effect is closely related to a concave depth of the piezoelectric layer 110 and a thickness of the electrode finger. The concave depth of the piezoelectric layer 110 and the thickness of the electrode finger need to be accurately controlled, and a process tolerance is small. After the decreased acoustic impedance cooperates with the increased acoustic impedance, if the acoustic resistance in the area in which the groove is located cannot match the acoustic impedance at another location of the piezoelectric layer 110, a suppression effect on the A1-3 harmonic is affected. In a structural design, the lamb wave resonator 100 shown in FIG. 4B is mainly configured to suppress the A1-3 harmonic.

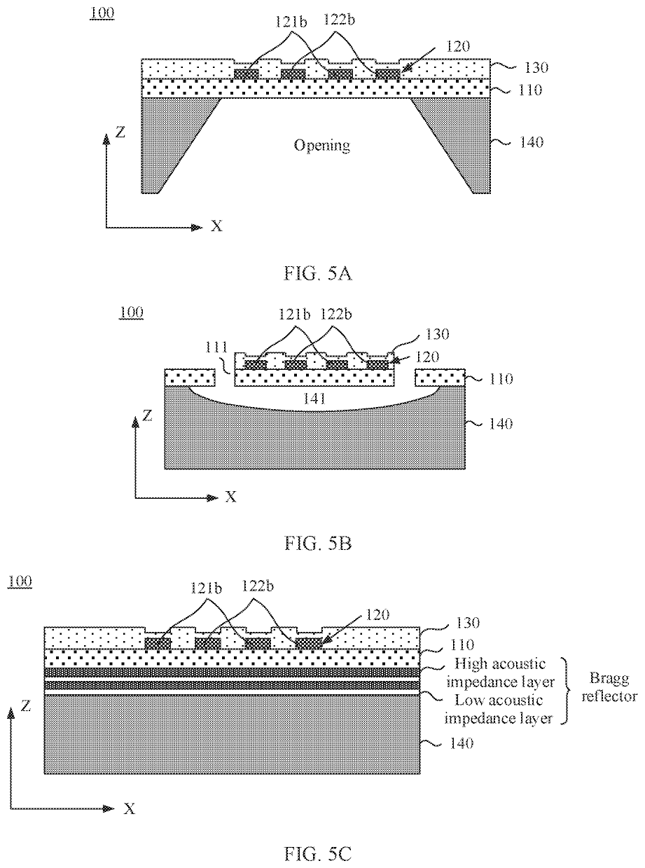

An embodiment of this application provides a lamb wave resonator 100. As shown in FIG. 5A, the lamb wave resonator 100 includes a substrate 140, a piezoelectric layer 110, an interdigital transducer 120, and a dielectric layer 130.

A material of the substrate 110 may be, for example, lithium niobate (LiNbO₃, LN), lithium tantalate (LiTaO₃, LT), quartz (quartz), silicon (Si), ceramics (ceramics), or glass (glass) Main components of the ceramics include, for example, silicate, aluminosilicate, melt-resistant metal oxide, metal nitride, and boride. Main components of the glass include, for example, Na2O·CaO·6SiO2 (Na2O·CaO·6SiO2).

A structure of the substrate 140 varies with a type of the lamb wave resonator 100. Any substrate structure in the conventional technology is applicable to this application.

For example. as shown in FIG. SA. the lamb wave resonator 100 is of a back etching structure. In this structure, the substrate 140 has an opening in a middle area, and the opening exposes the piezoelectric layer 110.

For example, a back etching process may be used to form the opening on the substrate 140, so that the piezoelectric layer 110 in the middle area is suspended, and a lower surface of the piezoelectric layer 110 in the middle area is in contact with air. Acoustic impedance of air is low, and an acoustic wave may be reflected back to the piezoelectric layer 110, to limit acoustic wave energy to being in the piezoelectric layer 110.

Alternatively, for example, as shown in FIG. 5B, the lamb wave resonator 100 is of an air gap structure. In this structure, a side that is of the substrate 140 and that faces the piezoelectric layer 110 has a groove 141 in a middle area.

For example, a release window 111 is etched on the piezoelectric layer 110 by using an etching process, and then the groove 141 is formed in the middle area of the substrate 140 by using a release process, so that the piezoelectric layer 110 in the middle area is suspended, and a lower surface of the piezoelectric layer 110 in the middle area is in contact with air. Acoustic impedance of air is low, and an acoustic wave may be reflected back to the piezoelectric layer 110, to limit the acoustic wave to being in the piezoelectric layer 110.

Alternatively, for example, as shown in FIG. 5C, the lamb wave resonator 100 is of a solid-state assembly structure. In this structure, a surface of the substrate 140 is a plane.

The lamb wave resonator 100 further includes a Bragg reflector (Bragg reflector) disposed below the piezoelectric layer 110. The Bragg reflector includes high acoustic impedance layers and low acoustic impedance layers that are alternately disposed. A material of the low acoustic impedance layer may be, for example, zinc oxide or silicon dioxide, and a material of the high acoustic impedance layer may be, for example, a heavy metal. The heavy metal refers to a metal with a density greater than 4.5 g/cm³, including gold, silver. copper, iron, mercury, lead, cadmium, and the like. An acoustic wave is reflected at a junction between the low acoustic impedance layer and the high acoustic impedance layer, and is reflected back to the piezoelectric layer. The low acoustic impedance layer is a film layer whose acoustic impedance is slightly lower than that of the high acoustic impedance layer, and acoustic impedance of both the low acoustic impedance layer and the high acoustic impedance layer may be greater than that of the piezoelectric layer. The Bragg reflector may limit the acoustic wave to being in the piezoelectric layer 110, thereby limiting the acoustic wave to being in the piezoelectric layer 110.

Alternatively, for example, as shown in FIG. 5D, the lamb wave resonator 100 is of a single reflection layer structure. In this structure, a surface of the substrate 140 is a plane.

The lamb wave resonator 100 further includes an acoustic wave reflection layer disposed below the piezoelectric layer 110, and when materials are selected for the acoustic wave reflection layer and the piezoelectric layer 110, acoustic impedance of the piezoelectric layer 110 needs to be greater than acoustic impedance of the acoustic wave reflection layer, so that an acoustic wave is reflected on a surface that is of the acoustic wave reflection layer and that faces the piezoelectric layer 110, and is reflected back to the piezoelectric layer 110.

It should be emphasized that, in this application, the acoustic impedance of the acoustic wave reflection layer needs to be less than the acoustic impedance of the piezoelectric layer 110.

and a relationship between the acoustic impedance of the acoustic wave reflection layer and acoustic impedance of the substrate 140 is not limited. The acoustic impedance of the acoustic wave reflection layer may be less than the acoustic impedance of the substrate 140. Alternatively. the acoustic impedance of the acoustic wave reflection layer may be greater than the acoustic impedance of the substrate 140. Alternatively, the acoustic impedance of the acoustic wave reflection layer may be equal to the acoustic impedance of the substrate 140.

Acoustic impedance (acoustic impedance) is a mechanical term, and refers to a complex ratio of pressure of a medium in an area of a wave front to a volume velocity of the medium passing through the area, and a unit of the acoustic impedance is Pascal per square meter per second (Pa·m⁻²s⁻¹).

The acoustic impedance Z₁₁₀ of the piezoelectric layer and the acoustic impedance Z₁₂₀ of the acoustic wave reflection layer may be separately calculated according to the following formulas:

$${Z}_{120} = {v}_{120} * {ρ}_{120} ; and$$

$${Z}_{110} = {v}_{110} * {ρ}_{110} .$$

For example, a lamb wave is a first-order antisymmetric (A1) mode, and the acoustic wave reflection layer is an isotropic material.

In this case,

$${Z}_{110} = {v}_{110} * {ρ}_{110} = \sqrt{\frac{{C}_{44}}{{ρ}_{110}}} * {ρ}_{110} = \sqrt{{C}_{44} * {ρ}_{110}} ; and$$

$${Z}_{120} = {v}_{120} * {ρ}_{120} = \sqrt{\frac{E}{2 * {ρ}_{120} * ( 1 + σ )}} * {ρ}_{120} = \sqrt{\frac{E * {ρ}_{120}}{2 * ( 1 + σ )}} .$$

Herein, v₁₂₀ and v₁₁₀ are shear wave velocities in a Z direction in the acoustic wave reflection layer and the piezoelectric layer 110, ρ₁₂₀ and ρ₁₁₀ are density of the acoustic wave reflection layer and the piezoelectric layer 110, C₄₄ is an elastic stiffness coefficient of the piezoelectric layer 110, E is a Young's modulus (Young's modulus) of the acoustic wave reflection layer, a unit of the Young's modulus is Pa, Mpa, or Gpa, and σ is a Poisson's ratio (Poisson's ratio) of the acoustic wave reflection layer.

In some embodiments, a larger acoustic wave reflection coefficient R of the surface that is of the acoustic wave reflection layer and that faces the piezoelectric layer 110 indicates a better acoustic wave limiting effect.

The acoustic wave reflection coefficient R may be calculated according to the following formula:

$$R = \vert \frac{{Z}_{110} - {Z}_{120}}{{Z}_{110} + {Z}_{120}} \vert .$$

The acoustic wave reflection coefficient R is related to the acoustic wave limiting effect.

In some embodiments, a value range of the acoustic wave reflection coefficient R is 0.5≤R<0.86. For example, a value of the acoustic wave reflection coefficient R is 0.6, 0.65, 0.7, 0.75, 0.8, or 0.85.

The acoustic wave reflection coefficient R is limited to being greater than or equal to 0.5, so that the acoustic wave can be effectively limited to being in the piezoelectric layer 110, and performance of the lamb wave resonator 100 provided in this embodiment of this application can be similar to performance of an air-gap lamb wave resonator.

In addition, a problem that, because the acoustic wave reflection coefficient R is too small (less than 0.5), the acoustic wave cannot be well limited to being in the piezoelectric layer 110, or the acoustic wave reflection layer used to limit the acoustic wave needs to be very thick and is difficult to implement in engineering can be resolved. In addition, a problem that, because the acoustic wave reflection coefficient R is too large (greater than 0.86), parameters such as density and a Young's modulus of a material of the acoustic wave reflection layer are small and the material is soft can be resolved. In a process of processing the lamb wave resonator 100 (for example, annealing after the piezoelectric layer is bonded), the acoustic wave reflection layer is prone to deformation, causing a problem that a yield rate of the product is affected because the piezoelectric layer 110 above the acoustic wave reflection layer is wrinkled or broken.

The material of the acoustic wave reflection layer may be any material that meets the acoustic wave reflection coefficient R.

In some embodiments, the material of the acoustic wave reflection layer is a macromolecular material (macromolecular material).

The macromolecular material, also referred to as a polymer material, is a material formed by using a polymer compound as a matrix and provided with other additives (additives).

For example, the material of the acoustic wave reflection layer includes polyimide (polyimide, PI), polydimethylsiloxane (polydimethylsiloxane, PDMS), polymethyl methacrylate (polymethyl methacrylate, PMMA), polyvinylidene fluoride (polyvinylidene fluoride, PVDF), polyethylene glycol terephthalate (polyethylene glycol terephthalate, PET), or the like.

For example, a process like spin coating, magnetron sputtering, physical vapor deposition, chemical vapor deposition, or epitaxial growth may be used to form the acoustic wave reflection layer. The process is simple, costs are low, and the yield rate is high.

As shown in Table 1, acoustic wave reflection coefficients R of several optional materials in this embodiment of this application may be obtained according to the foregoing formulas.

TABLE 1
Sound velocities, acoustic impedance, and acoustic
wave reflection coefficients of different materials

| | Vertical shear | Acoustic | Acoustic wave |
|---|---|---|---|
| | wave velocity | impedance Z | reflection |
| Material | (m/s) | (MRayl) | coefficient R |
| Z-cut LiNbO₃ | 3570 | 16.7793 | |
| PI | 943.28 | 1.2263 | 0.863786822 |
| PDMS | 16.107 | 0.0156 | 0.998142293 |
| PMMA | 948.87 | 1.1292 | 0.873892286 |
| PVDF | 838.56 | 1.4238 | 0.843565107 |
| PET | 1055.41 | 1.4248 | 0.843463835 |

In some embodiments, the acoustic wave reflection layer is a single film layer.

It may also be understood that the acoustic wave reflection layer 120 is one film layer. and is not a structure formed by stacking a plurality of film layers.

In this embodiment of this application, based on an acoustic impedance difference between the acoustic wave reflection layer and the piezoelectric layer 110, the acoustic wave is reflected on the surface that is of the acoustic wave reflection layer and that faces the piezoelectric layer 110. Therefore, the acoustic wave reflection layer may be a single film layer, and a structure and a preparation process are simple.

Certainly, the acoustic wave reflection layer 120 may alternatively include a plurality of film layers, and is a structure formed by stacking the plurality of film layers.

A specific structure of the acoustic wave reflection layer 120 is not limited in embodiments of this application, and a relationship between acoustic impedance of the plurality of film layers is not limited either, provided that the acoustic wave can be reflected on the surface that is of the acoustic wave reflection layer 120 and that faces the piezoelectric layer 130.

In some embodiments, a minimum thickness of the acoustic wave reflection layer is y, and the minimum thickness y may be calculated according to the following formula:

$$y = 77.75379 * {R}^{2} - 173.22328 * R + 97.70404 .$$

In this embodiment of this application, the acoustic wave reflection coefficient R of the acoustic wave reflection layer and the minimum thickness of the acoustic wave reflection layer vary with the material of the acoustic wave reflection layer.

In some embodiments, a thickness range of the acoustic wave reflection layer is 3.5 μm to 30 μm.

For example, a thickness of the acoustic wave reflection layer is 10 μm, 15 μm, 20 μm, or 25 μm.

As shown in FIG. 5A to FIG. SD, in the lamb wave resonator 100 provided in this embodiment of this application, a surface that is of the piezoelectric layer 110 and that faces the interdigital transducer 120 is a plane, and there is no need to form, on the surface of the piezoelectric layer 110, a groove for placing the interdigital transducer 120.

In some embodiments, a material of the piezoelectric layer 110 includes one or more piezoelectric materials such as lithium niobate (LiNbO₃, LN), lithium tantalate (LiTaO₃, LT), aluminum nitride (AlN), zinc oxide (ZnO)), or quartz. The material of the piezoelectric layer 130 may be lithium niobate in each cut direction.

In some embodiments, the material of the piezoelectric layer 110 is LiNbO₃, and a cut direction of the material is a Z-cut direction.

The Z-cut LiNbO₃ piezoelectric material can increase a bandwidth of the lamb wave resonator 100.

In some embodiments, the material of the piezoelectric layer 110 is LiNbO₃, and Euler angles of the material range from (0, 20, 0) to (0, 40, 0).

For example, the material of the piezoelectric layer 110 is LiNbO₃, and the Euler angles of the material are (0, 25. 0), (0, 30, 0), or (0, 35. 0).

Three numbers (α, β, γ) in Euler angles indicate that a single crystal that is directly pulled out first rotates by a around a z axis, then rotates by β around an x axis, and finally rotates by y around the z axis. In this way, a cut direction of the crystal is determined. Therefore, when the Euler angles are determined, the cut direction of the crystal is determined.

The Euler angles of the material of the piezoelectric layer 130 fall within the foregoing range, so that a resonance characteristic of the lamb wave resonator 100 can be improved.

In some embodiments, a thickness of the piezoelectric layer 110 is 0.2 μm to 1 μm.

For example, the thickness of the piezoelectric layer 110 is 0.3 μm, 0.4 μm, 0.5 μm, 0.6μm, 0.7 μm, 0.8 μm, or 0.9 μm.

The thickness of the piezoelectric layer 110 is directly related to a frequency of the lamb wave resonator. A thinner piezoelectric layer indicates a higher device frequency. In this application. the thickness of the piezoelectric layer is limited to 0.2 μm to 1 μm, so that the lamb wave resonator can be used in a high frequency.

The interdigital transducer 120 is disposed on a side that is of the piezoelectric layer 110 and that is away from the substrate 140. For example, the interdigital transducer 120 is disposed on a surface that is of the piezoelectric layer 110 and that is away from the substrate 140.

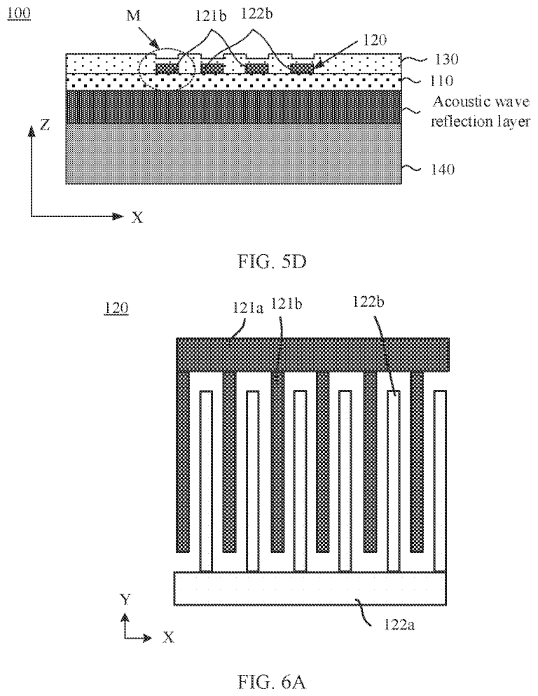

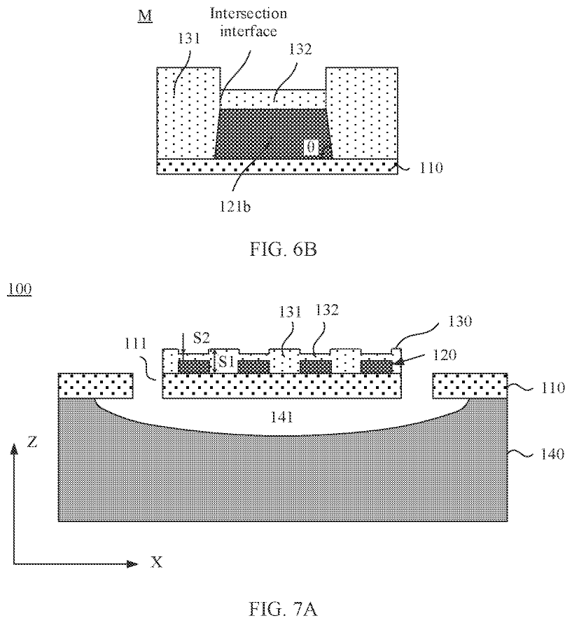

The interdigital transducer 120 may be understood as a metal pattern that is formed on the surface of the piezoelectric layer 110 and that is shaped like fingers of two hands crossing each other, and a function of the interdigital transducer 120 is to implement acoustic-electric energy conversion. In an embodiment, as shown in FIG. 6A, the interdigital transducer 120 includes a first busbar (busbar) 121a and a second busbar 122a that are disposed opposite to each other, a plurality of first electrode fingers (interdigitated transducer, IDT) 121b, and a plurality of second electrode fingers 122b. Extension directions of the first busbar 121a and the second busbar 122a are parallel to a first direction X. An extension direction of the first electrode fingers 121b is parallel to a second direction Y, the first electrode fingers 121b protrude from the first busbar 121a to the second busbar 122a, and the plurality of first electrode fingers 121b are coupled to the first busbar 121a. An extension direction of the second electrode fingers 122b is parallel to the second direction Y, the second electrode fingers 122b protrude from the second busbar 122a to the first busbar 121a, and the plurality of second electrode fingers 122b are coupled to the second busbar 122a. The first direction X intersects the second direction Y. Parallelism in embodiments of this application includes approximate parallelism, and deviations in a process error range (for example,) ±5° all belong to the parallelism in embodiments of this application.

The plurality of first electrode fingers 121b and the plurality of second electrode fingers 122b are alternately arranged between the first busbar 121a and the second busbar 122a in sequence in the first direction X, and the first electrode fingers 121b and the second electrode fingers 122b are not in contact with each other.

That “the plurality of first electrode fingers 121b and the plurality of second electrode fingers 122b are alternately arranged between the first busbar 121a and the second busbar 122a in sequence in the first direction X” means that between the first busbar 141a and the second busbar 142a, one second electrode finger 142b is disposed between every two first electrode fingers 141b, and one first electrode finger 141b is disposed between every two second electrode fingers 142b.

A quantity of first electrode fingers 121b and a quantity of second electrode fingers 122b in the interdigital transducer 120 are not limited, and may be set according to a requirement. The plurality of first electrode fingers 121b may be arranged at an equal pitch, or may be arranged at a non-equal pitch. Similarly, the plurality of second electrode fingers 122b may be arranged at an equal pitch, or may be arranged at a non-equal pitch. The first electrode finger 121b is used as an example. That the plurality of first electrode fingers 121b are arranged at a non-equal pitch means that a pitch between at least one pair of adjacent first electrode fingers 121b is different from a pitch between another pair of adjacent first electrode fingers 121b.

In addition, that the plurality of first electrode fingers 121b and the plurality of second electrode fingers 122b are alternately arranged in sequence may indicate that pitches between the first electrode fingers 121b and the second electrode fingers 122b that are adjacent are the same; or may indicate that pitches between a plurality of pairs of first electrode fingers 121b and second electrode fingers 122b that are adjacent are not totally the same. that is, a pitch between at least one pair of first electrode finger 121b and second electrode finger 122b that are adjacent is different from a pitch between another pair of first electrode finger 121b and second electrode finger 122b that are adjacent.

In some embodiments, a pitch between a first electrode finger 121b and a second electrode finger 122b that are adjacent ranges from 2 μm to 10 μm.

For example, the pitch between a first electrode finger 121b and a second electrode finger 122b that are adjacent ranges from 2 μm to 4 μm, 4 μm to 5 μm, 5 μm to 6 μm, 6 μm to 7 μm, 7 μm to 8 μm, 8 μm to 9 μm, or 9 μm to 10 μm.

The pitch between the first electrode finger 141b and the second electrode finger 142b directly affects the frequency of the lamb wave resonator 100, and also affects the bandwidth of the lamb wave resonator 100. Generally, a larger pitch indicates a wider bandwidth. Therefore, the pitch between a first electrode finger 141b and a second electrode finger 142b that are adjacent is limited to 2 μm to 10 μm, so that the lamb wave resonator 100 can operate in a 5th generation mobile communication technology (5th generation mobile communication technology, 5G) frequency band and have a wide bandwidth.

In some embodiments, a width of the first electrode finger 141b ranges from 200 nm to 1000 nm, and a width of the second electrode finger 142b ranges from 200 nm to 1000 nm.

For example, the widths of the first electrode finger 141b and the second electrode finger 142b range from 200 nm to 300 nm, from 300 nm to 400 nm, from 400 nm to 500 nm, from 500 nm to 600 nm, from 600 nm to 700 nm, from 700 nm to 800 nm, from 800 nm to 900 nm, or from 900 nm to 1000 nm.

Because a duty cycle mainly affects the bandwidth of the lamb wave resonator 100, the frequency of the lamb wave resonator 100 is also affected. However, Duty cycle-Width of an electrode finger/(Width of the electrode finger+Pitch between electrode fingers). When the pitch between the electrode fingers is determined, the width of the electrode finger is adjusted. to adjust the bandwidth and the frequency of the lamb wave resonator 100. Therefore, the widths of the first electrode finger 141b and the second electrode finger 142b that are adjacent are limited to 200 nm to 1000 nm, so that the lamb wave resonator 100 can operate in the 5G frequency band and have a wide bandwidth.

It may be understood that the pitch (pitch) between the first electrode finger 121b and the second electrode finger 122b and the finger widths of the first electrode finger 121b and the second electrode finger 122b are mainly affected by lithography and development processes, and a resonance frequency and the bandwidth of the lamb wave resonator 100 may be changed by adjusting the pitch between the first electrode finger 121b and the second electrode finger 122b and the finger widths of the first electrode finger 121b and the second electrode finger 122b, so that an electronic signal of a specific frequency can pass through the lamb wave resonator 100, and an electronic signal of another frequency is filtered out by the lamb wave resonator 100.

It should be noted that the first busbar 121a, the first electrode finger 121b, the second busbar 122a, and the second electrode finger 122b may be prepared at the same time. Alternatively, the first busbar 121a and the first electrode finger 121b may be prepared first, and then the second busbar 122a and the second electrode finger 122b are prepared. Alternatively, the second busbar 122a and the second electrode finger 122b are prepared first, and then the first busbar 121a and the first electrode finger 121b are prepared.

Materials of the first electrode finger 121b and the second electrode finger 122b may include one or more of aluminum (A1), copper (Cu), platinum (Pt), gold (Au), nickel (Ni), titanium (Ti), silver (Ag), chromium (Cr), molybdenum (Mo), tungsten (W), tantalum (Ta), and the like.

In the interdigital transducer 120 provided in this embodiment of this application, side surfaces that are of the first electrode fingers 121b and the second electrode fingers 122b and on which the first electrode fingers 121b and the second electrode fingers 122b intersect with the piezoelectric layer 110 are perpendicular to the piezoelectric layer 110. However, limited by a process, the side surfaces of the first electrode fingers 121b and the second electrode fingers 122b may alternatively have a specific tilt angle with the piezoelectric layer 110. For example, as shown in FIG. 6B (an enlarged diagram at a location M in FIG. 5D), a value of an included angle θ between the side surfaces of the first electrode fingers 121b and the second electrode fingers 122b and the piezoelectric layer 110 is 70°<θ≤90°.

With reference to FIG. 6A, it can be learned that the first electrode fingers 121b and the second electrode fingers 122b of the interdigital transducer 120 are shown in sectional views in FIG. 5A to FIG. 5D. In addition, in the accompanying drawings of embodiments of this application, the first direction X is an arrangement direction of the first electrode fingers 121b and the second electrode fingers 122b, the second direction Y is an extension direction of the first electrode fingers 121b or the second electrode fingers 122b. and a third direction Z is a thickness direction of the lamb wave resonator 100. The first direction X intersects the second direction Y. and the third direction Z is perpendicular to a plane on which the first direction X and the second direction Y are located.

For ease of description, the following uses an air-gap lamb wave resonator 100 as an example to describe a structure of a dielectric layer 130.

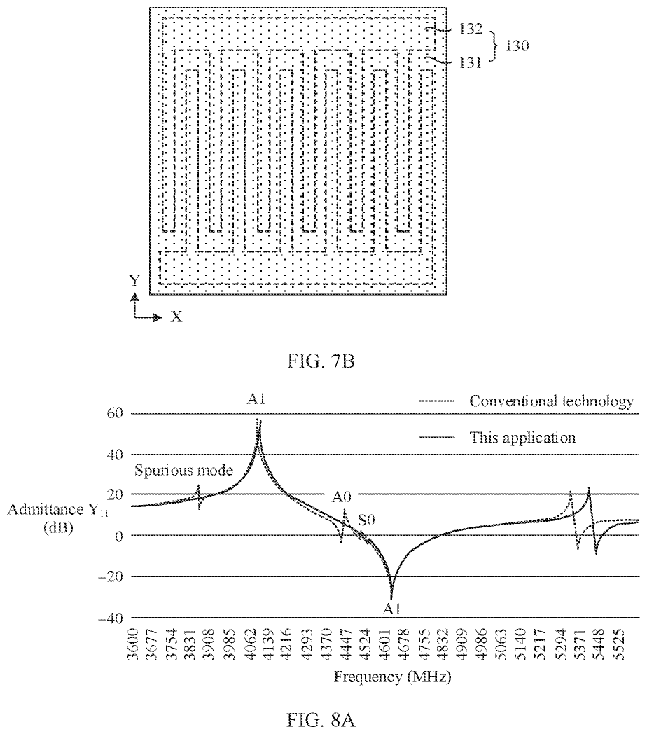

The dielectric layer 130 and an interdigital transducer 120 are located on a same side of a piezoelectric layer 110. For a structure of the dielectric layer 130, in some embodiments, as shown in FIG. 7A, the dielectric layer 130 includes a first part 131 and a second part 132, and the first part 131 is disposed on a surface of the piezoelectric layer 110. and is located on a periphery of first electrode fingers 121b and second electrode fingers 122b. The second part 132 is located on a top surface (a surface away from the piezoelectric layer 110) of the interdigital transducer 120.

Alternatively, it is understood that a film is formed on the surface of the interdigital transducer 120 to form the dielectric layer 130. A part of the dielectric layer 130 is used as the first part 131 in this embodiment of this application, falls into a gap of the interdigital transducer 120, and is in direct contact with the piezoelectric layer 110. The other part of the dielectric layer 130 is used as the second part 132 in this embodiment of this application, falls on the surface of the interdigital transducer 120, and is in contact with the interdigital transducer 120.

In other words, in the dielectric layer 130, a part in contact with the piezoelectric layer 110 is the first part 131, and a part in contact with the interdigital transducer 120 is the second part 132.

In some embodiments, the second part 132 has a first projection on the surface of the piezoelectric layer 110, the interdigital transducer 120 has a second projection on the surface of the piezoelectric layer 110, and the second projection includes the first projection. Alternatively, it is understood that the second part 132 is disposed on the top surface of the interdigital transducer 120.

For example, the first projection coincides with the second projection. Alternatively, for example, the second projection covers the first projection.

From a top view, as shown in FIG. 7B, a shape of the second part 133 of the dielectric layer 130 basically coincides with a shape of the interdigital transducer 120, and a structure other than the second part 133 is the first part 131.

As shown in FIG. 6B. when an included angle θ between side surfaces of the first electrode fingers 121b and the second electrode fingers 122b and the piezoelectric layer 110 is less than 90°, an intersection interface between a first part 131 and a second part 132 needs to correspond to a boundary of a top surface of a first electrode finger 121b and a second electrode finger 122b. In other words, a boundary of the second part 132 corresponds to the boundaries of the top surfaces of the first electrode fingers 121b and the second electrode fingers 122b.

Certainly, all location offsets in a process error range fall within the protection scope of embodiments of this application. A process error offset may be, for example, a left or right 150-nm offset of the intersection interface in a perspective of FIG. 6B.

In some embodiments, a thickness of the first part 131 is S1, a thickness of the second part 132 is S2, and S1>S2.

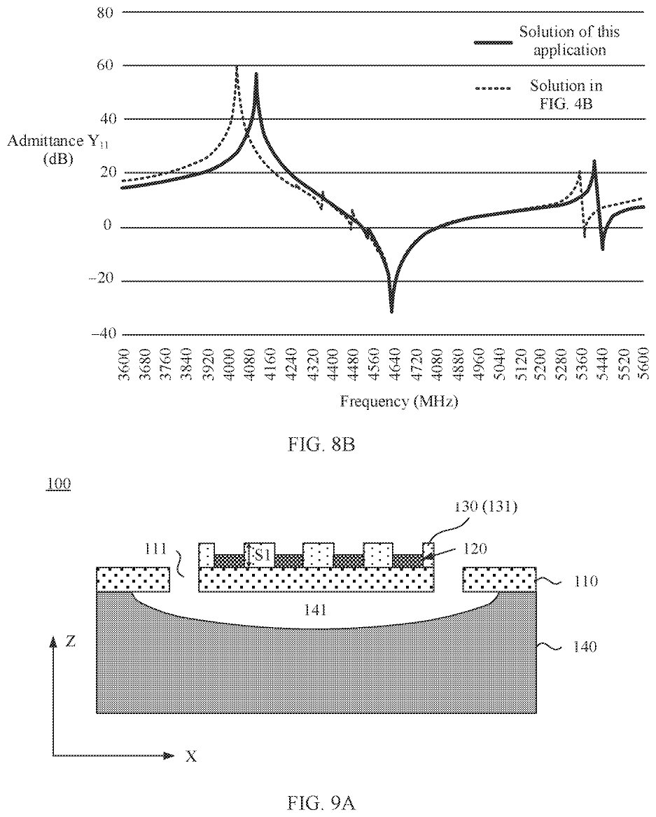

Finite element simulation is performed on the lamb wave resonator 100 provided in this embodiment of this application and a lamb wave resonator 100 provided in the conventional technology, and obtained admittance curves are shown in FIG. 8A. A solid line is an admittance curve of the lamb wave resonator 100 (S1>S2) provided in this embodiment of this application, and a dotted line is an admittance curve of the lamb wave resonator 100 (S1=S2) provided in the conventional technology.

It can be learned from the admittance curve of the lamb wave resonator 100 (S1=S2) in the conventional technology that. between positive and negative resonance peaks of an A1 mode. there is a clear lateral higher-order harmonic of an A0 mode and a clear lateral higher-order harmonic of an S0 mode (both of which are alternatively referred to as a spurious mode). At the same time, a spurious mode also appears on the left of a positive resonance peak of the A1 mode It can be learned from the admittance curve of the lamb wave resonator 100 (S1>S2) provided in this embodiment of this application that the lateral higher-order harmonic of the A0 mode and the lateral higher-order harmonic of the S0 mode between the positive and negative resonance peaks of the A1 mode are well suppressed, and the spurious mode on the left of the positive resonance peak of the A1 mode is also well suppressed, and even completely suppressed. The admittance curve of the lamb wave resonator 100 is smooth, and performance is good.

Therefore. in the lamb wave resonator 100 provided in this embodiment of this application, the thickness S2 of the second part 132 that is of the dielectric layer 130 and that is located above the interdigital transducer 120 is thinned, so that plate wave spurious modes such as the lateral higher-order harmonic of the A0 mode and the lateral higher-order harmonic of the S0 mode in the lamb wave resonator 100 can be suppressed, flatness in a passband can be improved, a loss can be reduced, and performance of the lamb wave resonator 100 can be improved.

In addition, in the lamb wave resonator 100 provided in this embodiment of this application, thinning the thickness S2 of the second part 132 that is of the dielectric layer 130 and that is located above the interdigital transducer 120 is equivalent to processing the dielectric layer 130. In comparison with processing the piezoelectric layer 110 in embodiments shown in FIG. 4B, a material of the dielectric layer 130 is a dielectric material. In the semiconductor field, a process of etching the dielectric material is mature, a mature process in the conventional technology may be used to prepare the dielectric layer 130 in this application. However, a material of the piezoelectric layer 110 is a piezoelectric material. In the semiconductor field, there are few processes for etching the piezoelectric material, and the process needs to be further studied and controlled to achieve the objective. Therefore, a preparation process of the lamb wave resonator 100 provided in this embodiment of this application is simple, and has a low process difficulty and low preparation costs, so that a yield rate of the lamb wave resonator 100 can be improved. In addition, FIG. 8B shows the admittance curve of the lamb wave resonator 100 provided in this embodiment of this application and the admittance curve of the lamb wave resonator 100 shown in FIG. 4B. It can be found through comparison between the two admittance curves that, the lamb wave resonator 100 provided in this embodiment of this application has a better suppression effect on the plate wave spurious modes such as the lateral higher-order harmonic of the A0 mode and the lateral higher-order harmonic of the S0 mode.

In an embodiment, the lamb wave resonator 100 includes a frequency shift laver, and the frequency shift layer is configured to adjust a frequency of the lamb wave resonator 100. The frequency shift layer is disposed on a side that is of the interdigital transducer 120 and that is away from the piezoelectric layer 110.

A material of the frequency shift layer may be, for example, silicon nitride (SiN). aluminum oxide (Al₂O₃), or silicon oxide (SiO₂).

The frequency shift layer may be directly used as the dielectric layer 130 in the lamb wave resonator 100 provided in this embodiment of this application, where only the frequency shift layer needs to be processed, and no new film layer needs to be added, so that the lamb wave resonator 100 is slightly modified.

In an embodiment, the lamb wave resonator 100 disposed with the frequency shift layer (for example, a thinned frequency shift layer) may be used in a filter that is in a 5th generation mobile communication technology (5th generation mobile communication technology, 5G) frequency band like an n77 frequency band (3.3 GHZ to 4.2 GHZ), an n78 frequency band (3.3

GHz to 3.8 GHz), or an n79 frequency band (4.4 GHz to 5.0 GHz), and whose operating frequency ranging from 450 MHz to 6000 MHz in a frequency band below 6 GHz (sub-6 GHz frequency band).

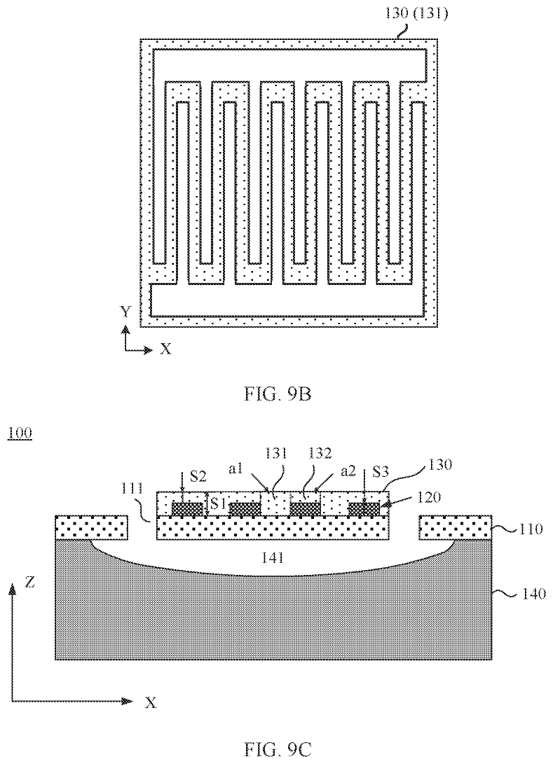

For values of S1 and S2, in some embodiments, as shown in FIG. 9A, S2=0.

Alternatively, it is understood that the dielectric layer 130 includes the first part 131, and the first part 131 is disposed on the surface of the piezoelectric layer 110, and is located on the periphery of the first electrode fingers 121b and the second electrode fingers 122b. The dielectric layer 130 does not include the second part 132 located above the interdigital transducer 120.

From a top view, a structure of the dielectric layer 130 (the first part 131) is shown in FIG. 9B. The dielectric layer 130 has a hollow-out pattern, and a top view of the hollow-out pattern basically coincides with a top view of the interdigital transducer 120.

It is found through finite element simulation that when the second part 132 that is of the dielectric layer 130 and that is located above the interdigital transducer 120 is completely removed, plate wave spurious modes such as the lateral higher-order harmonic of the A0 mode and the lateral higher-order harmonic of the S0 mode in the lamb wave resonator 100 can still be suppressed.

In some other embodiments, as shown in FIG. 9C, 0<S2<S1.

Alternatively, it is understood that the dielectric layer 130 includes the first part 131 and the second part 132, and the first part 131 is disposed on the surface of the piezoelectric layer 110, and is located on the periphery of the first electrode fingers 121b and the second electrode fingers 122b. The second part 132 is located on the top surface of the interdigital transducer 120.

After different values are given to S1 and S2, finite element simulation is performed on the lamb wave resonator 100 to obtain the following Table 2.

TABLE 2
Suppression of the lateral higher-order harmonic of the A0 mode and the lateral
higher-order harmonic of the S0 mode under different combinations of S1 and S2

| | | S1 | | | | | | | | | | |
|---|---|---|---|---|---|---|---|---|---|---|---|---|
| S2 | | 90 nm | 95 nm | 100 nm | 105 nm | 110 nm | 115 nm | 120 nm | 125 nm | 130 nm | 135 nm | 140 nm |
| 0 | nm | 1 | 1 | 1 | 1 | 1 | 2 | 2 | 2 | 2 | 2 | 2 |
| 5 | nm | 1 | 1 | 1 | 1 | 1 | 2 | 2 | 2 | 2 | 1 | 2 |
| 10 | nm | 1 | 1 | 1 | 1 | 1 | 2 | 2 | 2 | 2 | 1 | 2 |
| 15 | nm | 1 | 1 | 1 | 1 | 1 | 2 | 2 | 2 | 2 | 1 | 2 |
| 20 | nm | 1 | 1 | 1 | 1 | 1 | 2 | 2 | 2 | 2 | 1 | 2 |
| 25 | nm | 1 | 1 | 1 | 1 | 1 | 2 | 2 | 2 | 2 | 1 | 2 |
| 30 | nm | 1 | 1 | 1 | 1 | 1 | 2 | 2 | 2 | 2 | | 2 |
| 35 | nm | 1 | 1 | 1 | 1 | 1 | 2 | 2 | 2 | 2 | | 2 |
| 40 | nm | 1 | 1 | 1 | 1 | 1 | 2 | 2 | 2 | 2 | | 2 |
| 45 | nm | | 1 | 1 | 1 | 1 | 2 | 2 | 2 | 2 | | 2 |
| 50 | nm | | | 1 | 1 | 1 | 2 | 2 | 2 | 1 | | 2 |
| 55 | nm | | | | 1 | 1 | 1 | 2 | 2 | 1 | | 2 |
| 60 | nm | | | | | 1 | 1 | 1 | 1 | | | 2 |
| 65 | nm | | | | | | 1 | 1 | 1 | | | 2 |
| 70 | nm | | | | | | | 1 | 1 | | | 2 |
| 75 | nm | | | | | | | | 1 | | | 2 |
| 80 | nm | | | | | | | | | | | 2 |
| 85 | nm | | | | | | | | | | | 2 |
| 90 | nm | | | | | | | | | | | 1 |

A combination of S1 and S2 corresponding to the number 1 in Table 1 represents that under corresponding values of S1 and S2, suppression of the lateral higher-order harmonic of the A0 mode and the lateral higher-order harmonic of the S0 mode is good (which may be understood as that, for example, peak-to-peak values of the lateral higher-order harmonic of the A0 mode and the lateral higher-order harmonic of the S0 mode are less than 5 dB). A combination of S1 and S2 corresponding to the number 2 in Table 1 represents that under corresponding values of S1 and S2, the lateral higher-order harmonic of the A0 mode and the lateral higher-order harmonic of the S0 mode are almost completely suppressed (which may be understood as that, for example, peak-to-peak values of the lateral higher-order harmonic of the A0 mode and the lateral higher-order harmonic of the S0 mode are less than 2.5 dB).

For example, when a value of the thickness S1 of the first part 131 is 115 nm, and a value of the thickness S2 of the second part 132 is 50 nm, the lateral higher-order harmonic of the A0 mode and the lateral higher-order harmonic of the S0 mode are almost completely suppressed. When a value of the thickness S1 of the first part 131 is 115 nm, and a value of the thickness S2 of the second part 132 is 55 nm, a suppression effect on the lateral higher-order harmonic of the A0 mode and the lateral higher-order harmonic of the S0 mode is good.

Based on this, a difference between S1 and S2 affects the suppression effect on the lateral higher-order harmonic of the A0 mode and the lateral higher-order harmonic of the S0 mode. In some embodiments, 50 nm≤S1−S2≤S1.

For example, a value of S1−S2 is 55 nm, 60 nm, 65 nm, 70 nm, 75 nm, 80 nm, 85 nm 90 nm, 95 nm, 100 nm, 105 nm, 110 nm, 115 nm, 120 nm, 125 nm, 130 nm, 135 nm, 140 nm, 145 nm, 150 nm, 155 nm, 160 nm, 165 nm, 170 nm, 175 nm, 180 nm, 185 nm, 190 nm, or 195 nm.

The difference between the thickness of the first part 131 and the thickness of the second part 132 is limited to 50 nm to S1, so that the lateral higher-order harmonic of the A0 mode and the lateral higher-order harmonic of the S0 mode can be well suppressed.

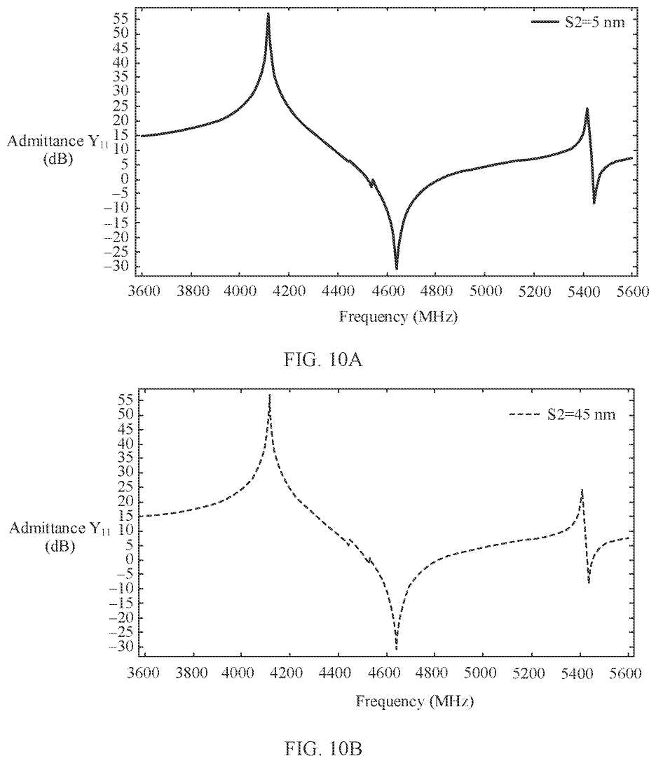

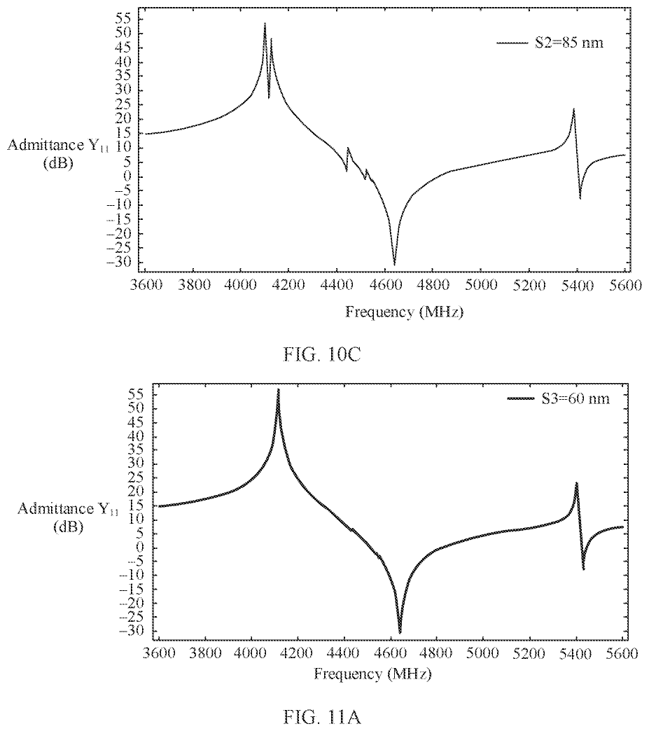

The thickness S1 of the first part 131 is fixed to 115 nm, and the value of the thickness S2 of the second part 132 ranges from 5 nm to 85 nm. Admittance curves of the lamb wave resonator 100 under different S2 are obtained through finite element simulation. FIG. 10A to FIG. 10C show admittance curves of the lamb wave resonator 100 in cases in which the thickness S1 of the first part 131 is 115 nm and S2 is 5 nm, 45 nm, and 85 nm It is found that when S2 changes from 5 nm to 85 nm, a negative resonance frequency of the A1 mode almost remains unchanged, and a fluctuation of a positive resonance frequency is within 5 MHZ.

In other words, when the thickness S1 of the first part 131 is fixed, the thickness S2 of the second part 132 may have a large variation range. In this large range, the lateral higher-order harmonic of the A0 mode and the lateral higher-order harmonic of the S0 mode can be suppressed. Even if the thickness S2 is not fixed to a specific value or a small range, the lateral higher-order harmonic of the A0 mode and the lateral higher-order harmonic of the S0 mode can still be suppressed.

In addition, it can be learned from Table 1 that the value of the thickness S1 of the first part 131 may also be in a large range. In this large range, the lateral higher-order harmonic of the A0 mode and the lateral higher-order harmonic of the S0 mode can be suppressed. Even if the thickness S2 is not fixed to a specific value or a small range, the lateral higher-order harmonic of the A0 mode and the lateral higher-order harmonic of the S0 mode can still be suppressed.

It can be learned from the foregoing descriptions that, in the lamb wave resonator 100 provided in this embodiment of this application, the thickness S1 of the first part 131 of the dielectric layer 130 has a large value range, and the thickness S2 of the second part 132 of the dielectric layer 130 also has a large value range. Therefore, S1-S2 also has a large value range Therefore, a value range of a thickness of the dielectric layer 130 in the lamb wave resonator 100 provided in this embodiment of this application is wide, and the lamb wave resonator 100 has a large tolerance range for a process error.

In some embodiments, 20 nm≤S1≤200 nm.

For example, the value of the thickness S1 of the first part 131 of the dielectric layer 130 ranges from 30 nm to 50 nm, from 50 nm to 70 nm, from 70 nm to 90 nm, from 90 nm to 100 nm, from 100 nm to 120 nm, from 120 nm to 140 nm, from 140 nm to 145 nm. from 145 nm to 150 nm, from 150 nm to 155 nm, from 155 nm to 160 nm, from 160 nm to 165 nm, from 165 nm to 170 nm, from 170 nm to 175 nm, from 175 nm to 180 nm, from 180 nm to 185 nm, from 185 nm to 190 nm, from 190 nm to 195 nm, or from 195 nm to 200 nm.

The value of the thickness S1 of the first part 131 of the dielectric layer 130 is limited to 20 nm to 200 nm, so that the lateral higher-order harmonic of the A0 mode and the lateral higher-order harmonic of the S0 mode can be suppressed while a thickness of the lamb wave resonator 100 is not excessively increased.

In some embodiments. 65 nm≤S1−S2≤S1, and 110 nm≤S1≤140 nm.

To ensure the suppression effect on the lateral higher-order harmonic of the A0 mode and the lateral higher-order harmonic of the S0 mode, for example, a case in which S1=135 nm may be avoided. In other words, when the lamb wave resonator 100 is designed. the thickness of the first part 131 is not designed to be 135 nm.

The value of S1-S2 is limited to being greater than 65 nm, and the value of S1 is limited to 110 nm to 140 nm, so that the lateral higher-order harmonic of the A0 mode and the lateral higher-order harmonic of the S0 mode can almost be completely suppressed, and the performance of the lamb wave resonator 100 is good.

In some embodiments, a value range of a thickness of the interdigital transducer 120 is 60 nm to 140 nm.

For example, a value of the thickness of the interdigital transducer 120 ranges from 70 nm to 75 nm, from 75 nm to 80 nm, from 80 nm to 85 nm, from 85 nm to 90 nm, from 90 nm to 95 nm, from 95 nm to 100 nm. from 100 nm to 105 nm, from 105 nm to 110 nm from 110 nm to 115 nm. from 115 nm to 120 nm from 120 nm to 125 nm, from 125 nm to 130 nm, from 130 nm to 135 nm, or from 135 nm to 140 nm.

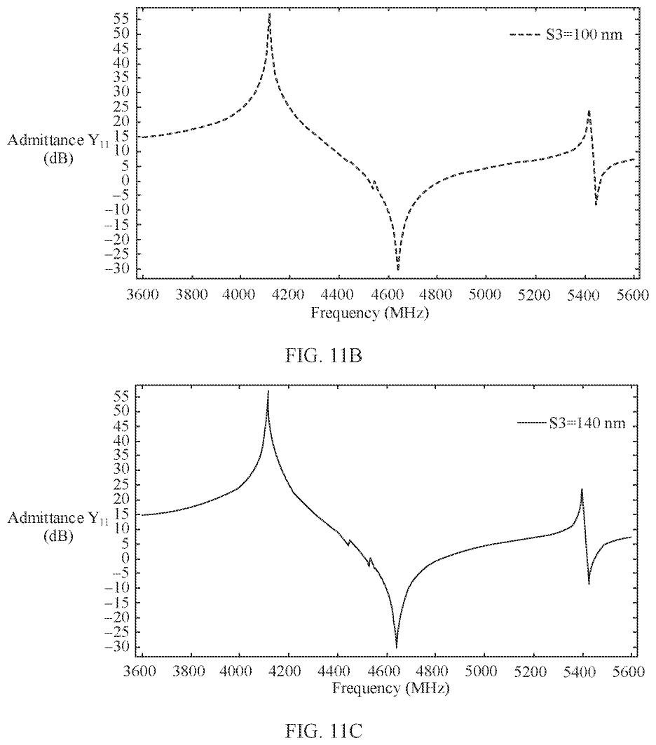

The thickness S1 of the first part 131 is fixed to 115 nm, and the thickness S2 of the second part 132 is fixed to 0 nm. A material of the interdigital transducer 120 is aluminum, and a value of the thickness S3 of the interdigital transducer 120 ranges from 20 nm to 160 nm. Admittance curves of the lamb wave resonator 100 corresponding to interdigital transducers 120 with different thicknesses are obtained through finite element simulation. FIG. 11A to FIG. 11C show admittance curves of the lamb wave resonator 100 in cases in which the thickness S3 of the interdigital transducer 120 is 60 nm, 100 nm, and 140 nm. It is found that changing the thickness S3 of the interdigital transducer 120 can also suppress the lateral higher-order harmonic of the A0 mode and the lateral higher-order harmonic of the S0 mode. When the thickness of the interdigital transducer 120 ranges from 60 nm to 140 nm, a suppression effect on the lateral higher-order harmonic of the A0 mode and the lateral higher-order harmonic of the S0 mode is good.

Therefore, in the lamb wave resonator 100 provided in this embodiment of this application, the value range of the thickness of the interdigital transducer 120 is wide, so that the lamb wave resonator 100 may be used in scenarios that have different requirements on the thickness of the interdigital transducer 120, and an application scope is wide.

It can be learned from the foregoing descriptions that, in the lamb wave resonator 100 provided in this embodiment of this application, the value range of the thickness S1 of the first part 131 of the dielectric layer 130 is wide, the value range of the difference between the thickness S1 of the first part 131 and the thickness S2 of the second part of the dielectric layer 130 is wide. and the value range of the interdigital transducer 120 is also wide.

Therefore, in a combination of different thicknesses, a case in which a top surface a1 of the first part 131 is flush with a top surface a2 of the second part 132, as shown in FIG. 9C, may occur on the dielectric layer 130.

The top surface a1 of the first part 131 may be understood as a surface that is of the first part 131 and that is away from the piezoelectric layer 110. The top surface a2 of the second part 132 may be understood as a surface that is of the second part 132 and that is away from the piezoelectric layer 110.

That a top surface a1 of the first part 131 is flush with a top surface a2 of the second part 132 may be understood as that a distance from the top surface a1 of the first part 131 to the piezoelectric layer 110 is equal to a distance from the top surface a2 of the second part 132 to the piezoelectric layer 110.

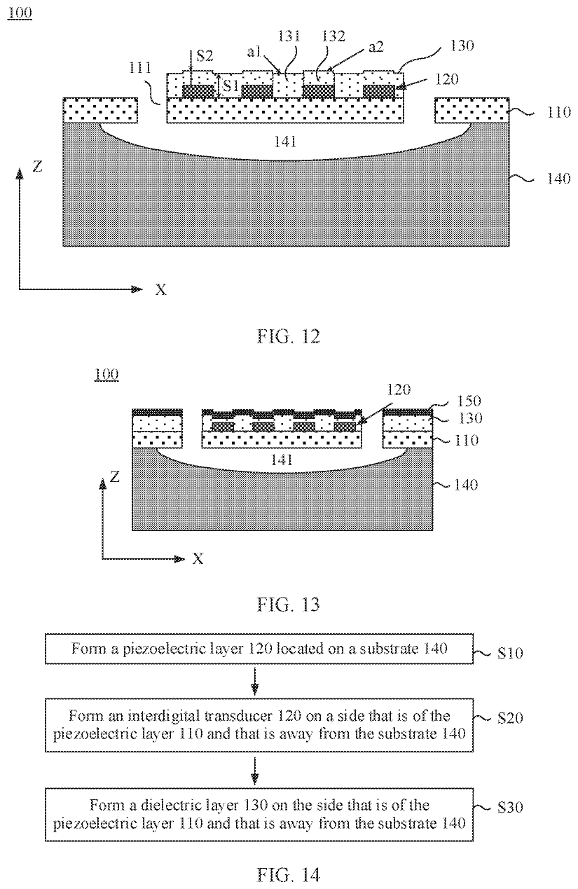

In a combination of different thicknesses, a case in which a top surface a1 of the first part 131 is lower than a top surface a2 of the second part 132, as shown in FIG. 12, may alternatively occur on the dielectric layer 130.

Similarly, that a top surface a1 of the first part 131 is lower than a top surface a2 of the second part 132 may be understood as that a distance from the top surface a1 of the first part 131 to the piezoelectric layer 110 is less than a distance from the top surface a2 of the second part 132 to the piezoelectric layer 110.

In a combination of different thicknesses, a case in which a top surface a1 of the first part 131 is higher than a top surface a2 of the second part 132. as shown in FIG. 7A, may alternatively occur on the dielectric layer 130.

In some embodiments, in the lamb wave resonator 100 provided in this embodiment of this application, thicknesses at locations of the first part 131 of the dielectric layer 130 are equal, and thicknesses at locations of the second part 132 are equal.

Certainly, being equal herein is not limited to being absolutely equal, and being approximately equal also falls within the protection scope of embodiments of this application. In other words, a thickness change in a process error range falls within the protection scope of embodiments of this application. For example, a thickness change in a range of ±3% falls within the protection scope of embodiments of this application.

For a material of the dielectric layer 130, in some embodiments, the material of the dielectric layer 130 includes silicon nitride (Si₃N₄), aluminum oxide (Al₂O₃), or silicon oxide (SiO₂).

It should be noted herein that a size of the dielectric layer 130 is not limited in embodiments of this application. As shown in FIG. 12, the dielectric layer 130 may be located only in a central area of the piezoelectric layer 110, and surrounds the interdigital transducer 120. In some embodiments, the dielectric layer 130 may alternatively be located in areas that are of the piezoelectric layer 110 and that are on two sides of a release window 111.

In addition, in the lamb wave resonator 100 provided in this embodiment of this application, the dielectric layer 130 may also be used as a frequency shift layer of the lamb wave resonator 100.

In this case, the material of the dielectric layer 130 may be, for example, Si₃N₄, Al₂O₃, or SiO₂.

In this application, when the lamb wave resonator 100 includes the frequency shift layer, a structure of another film layer in the lamb wave resonator 100 does not need to be changed, and a thickness of the frequency shift layer may be adjusted, to adjust the frequency of the lamb wave resonator 100 to a required value.

In the lamb wave resonator 100 provided in this embodiment of this application, the dielectric layer 130 may also be used as a temperature compensation layer of the lamb wave resonator 100.

In this case, the material of the dielectric layer 130 may be, for example, SiO₂.

In this application, when the lamb wave resonator 100 includes the temperature compensation layer, temperature compensation may be performed on the lamb wave resonator 100 through the temperature compensation layer. so that an absolute value of a temperature coefficient of frequency (TCF) of the lamb wave resonator 100 decreases.

In the lamb wave resonator 100 provided in this embodiment of this application, the dielectric layer 130 may also be used as a passivation layer of the lamb wave resonator 100.

In this case, the material of the dielectric layer 130 may be, for example, Si₃N₄, Al₂O₃, or SiO₂.

In this application, when the lamb wave resonator 100 includes the passivation layer, the lamb wave resonator 100 may be protected through the passivation layer, to prolong a service life of the lamb wave resonator 100.

In this case, for example, a temperature compensation layer or a frequency shift layer may be further disposed on a side that is of the piezoelectric layer 110 and that faces the substrate 140.

In some embodiments, as shown in FIG. 13, on the basis of including the dielectric layer 130, the lamb wave resonator 100 further includes a passivation layer 150. The passivation layer 150 is disposed on a side that is of the dielectric layer 130 and that is away from the piezoelectric layer 110, and a value range of a thickness of the passivation layer 150 is 1 nm to 50 nm.

A material of the passivation layer 150 may be, for example, Si₃N₄, Al₂O₃, or SiO₂.

The passivation layer 150 is disposed, so that a film layer between the passivation layer 150 and the substrate 140 can be protected. so as to prolong a service life of the lamb wave resonator 100.

The following schematically describes a preparation method of the lamb wave resonator 100 provided in this embodiment of this application.

In some embodiments, as shown in FIG. 14, a preparation method of a lamb wave resonator 100 includes the following steps.

S10: Form a piezoelectric layer 110 located on a substrate 140.

A structure of the substrate 140 and a preparation sequence of the substrate 140 and the piezoelectric layer 110 vary with a type of the lamb wave resonator 100. For details, refer to the foregoing descriptions of the substrate 140 and the preparation method thereof, and details are not described herein again.

For example, the piezoelectric layer 110 may be formed by using a process like magnetron sputtering, physical vapor deposition, chemical vapor deposition, epitaxial growth, or crystal bonding (bonding).

S20: Form an interdigital transducer 120 on a side that is of the piezoelectric layer 110 and that is away from the substrate 140.

A preparation process of the interdigital transducer 120 is not limited in embodiments of this application. All processes used to prepare the interdigital transducer 120 in a conventional technology are applicable to this application.

S30: Form a dielectric layer 130 on the side that is of the piezoelectric layer 110 and that is away from the substrate 140.

In some embodiments, the dielectric layer 130 includes a first part 131, and the first part 131 is disposed on a surface of the piezoelectric layer 110, and is located on a periphery of first electrode fingers 121b and second electrode fingers 122b.

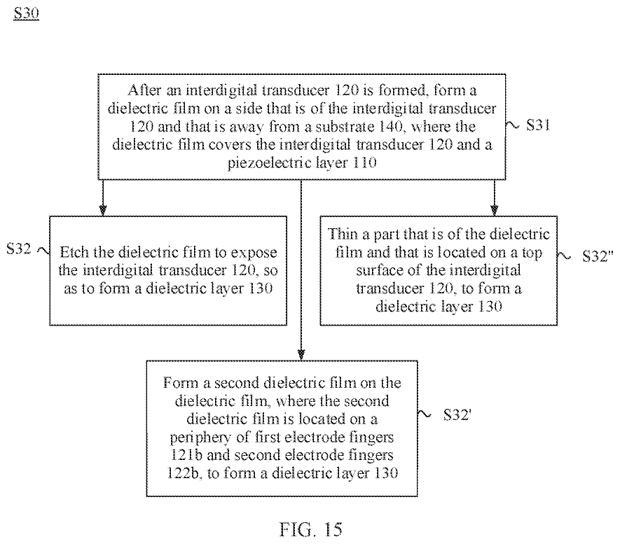

In this case, for example, as shown in FIG. 15, step S30 includes the following steps.

S31: After the interdigital transducer 120 is formed, form a dielectric film on a side that is of the interdigital transducer 120 and that is away from the substrate 140, where the dielectric film covers the interdigital transducer 120 and the piezoelectric layer 110.

S32: Etch the dielectric film to expose the interdigital transducer 120, so as to form the dielectric layer 130.

In some other embodiments, the dielectric layer 130 includes a first part 131 and a second part 132. The first part 131 is disposed on a surface of the piezoelectric layer 110, and the second part 132 is disposed on a surface of the interdigital transducer 120.

For example, as shown in FIG. 15, step S30 includes the following steps.

S31: After the interdigital transducer 120 is formed, form a dielectric film on a side that is of the interdigital transducer 120 and that is away from the piezoelectric layer 110.

In this case, the dielectric film may be understood as a first dielectric film, the first dielectric film covers the interdigital transducer 120 and the piezoelectric layer 110, and a thickness of the first dielectric film is basically equal to a thickness of the to-be-formed second part 132.

S32′: Form a second dielectric film on the dielectric film (the first dielectric film). where the second dielectric film is located on the periphery of the first electrode fingers 121b and the second electrode fingers 122b, to form the dielectric layer 130.

The second dielectric film and a part that is of the first dielectric film and that is located on the surface of the piezoelectric layer 110 form the first part 131 of the dielectric layer 130, and a part that is of the first dielectric film and that is located on a top surface of the interdigital transducer 120 is used as the second part 132 of the dielectric layer 130.

The thickness of the second dielectric film is adjusted, so that a top surface a1 of the first part 131 is flush with a top surface a2 of the second part 132, or a top surface a1 of the first part 131 is lower than a top surface a2 of the second part 132, or a top surface a1 of the first part 131 is higher than a top surface a2 of the second part 132.

Alternatively, for example, as shown in FIG. 15, step S30 includes the following steps.

S31: After the interdigital transducer 120 is formed, form a dielectric film on a side that is of the interdigital transducer 120 and that is away from the piezoelectric layer 110.

In this case, the dielectric film may be understood as a third dielectric film, and the third dielectric film covers the interdigital transducer 120 and the piezoelectric layer 110. A thickness of the third dielectric film varies with a subsequent used thinning process. The following describes the thickness of the third dielectric film with reference to the thinning process.

S32″: Thin a part that is of the dielectric film (the third dielectric film) and that is located on the top surface of the interdigital transducer 120, to form the dielectric layer 130.

A part that is of the third dielectric film and that is located on the surface of the piezoelectric layer 110 is used as the first part 131. and the thinned part of the third dielectric film is used as the second part 132.

For the thinning process, for example, the third dielectric film may be thinned as a whole by using a chemical mechanical polishing (chemical mechanical polishing, CMP) process, and thinning is stopped until a thickness of the part that is of the third dielectric film and that is located on the top surface of the interdigital transducer 120 meets a thickness of the to-be-formed second part 132.

In this case, the thickness of the third dielectric film needs to be greater than a thickness of the to-be-formed first part 131.

It may be understood that, after thinning is performed by using the CMP process, a top surface a1 of the formed first part 131 of the dielectric layer 130 is flush with a top surface a2 of the second part 132.

For the thinning process, a process like etching or corrosion may alternatively be used to selectively thin the part that is of the third dielectric film and that is located on the surface of the piezoelectric layer 110, to form the second part 132.

In this case, the thickness of the third dielectric film needs to be equal to a thickness of the to-be-formed first part 131.

A thinning degree is controlled, so that a top surface a1 of the first part 131 is flush with a top surface a2 of the second part 132, or a top surface a1 of the first part 131 is lower than a top surface a2 of the second part 132, or a top surface a1 of the first part 131 is higher than a top surface a2 of the second part 132.

According to the preparation method of the lamb wave resonator 100 provided in this embodiment of this application, the dielectric layer 130 required in this embodiment of this application may be formed by controlling a process for forming the dielectric layer 130, to provide a lamb wave resonator that can suppress a lateral higher-order harmonic of an A0 mode and a lateral higher-order harmonic of an S0 mode. The process of processing the dielectric material is simple and easy to implement, and a yield rate is high.

The foregoing descriptions are merely specific implementations of this application, but are not intended to limit the protection scope of this application. Any variation or replacement within the technical scope disclosed in this application shall fall within the protection scope of this application. Therefore, the protection scope of this application shall be subject to the protection scope of the claims.

1-19. (canceled)

20. A filter, comprising:
a plurality of cascaded lamb wave resonators, wherein at least one lamb wave resonator of the cascaded lamb wave resonators comprises:
a substrate;
a piezoelectric layer coupled to the substrate and comprising a first side proximal to the substrate and a second side distal from the substrate;
an interdigital transducer disposed on the second side, wherein the interdigital transducer comprises a plurality of first electrode fingers and a plurality of second electrode fingers extending in a first direction, wherein the plurality of first electrode fingers and the plurality of second electrode fingers are alternately arranged in a second direction that intersects with the first direction; and
a dielectric layer located on the second side,
wherein the dielectric layer comprises a first part disposed on the piezoelectric layer and located on peripheries of the first electrode fingers and the second electrode fingers.

21. The filter of claim 20, wherein the dielectric layer further comprises a second part, wherein the second part is located on a surface of the interdigital transducer distal from the substrate, and wherein a first thickness (S1) of the first part is greater than a second thickness (S2) of the second part.

22. The filter of claim 21, wherein (S1−S2)≥50 nanometers (nm).

23. The filter of claim 21, wherein 20 nanometers (nm)≤S1≤200 nm.

24. The filter of claim 21, wherein (S1−S2)≥65 nanometers (nm), and wherein 110 nm≤S1≤140 nm.

25. The filter of claim 20, wherein a thickness of the interdigital transducer is 60 nanometers (nm) to 140 nm.

26. The filter of claim 21, wherein a first top surface of the first part is flush with a second top surface of the second part.

27. The filter of claim 21, wherein the second part comprises a first projection on the piezoelectric layer, wherein the interdigital transducer comprises a second projection on the piezoelectric layer, and wherein the second projection envelops the first projection.

28. The filter of claim 20, wherein the at least one lamb wave resonator further comprises a passivation layer disposed on the dielectric layer distal from the piezoelectric layer, and wherein a thickness of the passivation layer ranges from 1 nanometer (nm) to 50 nm.

29. The filter of claim 20, wherein the dielectric layer comprises silicon oxide (SiO₂), silicon nitride (Si₃N₄), or aluminum oxide (Al₂O₃).

30. A radio frequency device, comprising:
a power amplifier; and
a filter coupled to the power amplifier, wherein the filter comprises a plurality of cascaded lamb wave resonators, and wherein at least one lamb wave resonator of the cascaded lamb wave resonators comprises:
a substrate;
a piezoelectric layer coupled to the substrate and comprising a first side proximal to the substrate and a second side distal from the substrate;
an interdigital transducer disposed on the second side, wherein the interdigital transducer comprises a plurality of first electrode fingers and a plurality of second electrode fingers extending in a first direction, wherein the plurality of first electrode fingers and the plurality of second electrode fingers are alternately arranged in a second direction; and
a dielectric layer, located on the second side,
wherein the dielectric layer comprises a first part disposed on the piezoelectric layer and located on peripheries of the first electrode fingers and the second electrode fingers.

31. The radio frequency device of claim 30, wherein the dielectric layer further comprises a second part, wherein the second part is located on a surface of the interdigital transducer distal from the substrate, and wherein a first thickness (S1) of the first part is greater than a second thickness (S2) of the second part.

32. The radio frequency device of claim 31, wherein (S1−S2)≥50 nanometers (nm).

33. The radio frequency device of claim 31, wherein a first top surface of the first part is higher than a second top surface of the second part, or the first top surface of the first part is lower than the second top surface of the second part.

34. A method of making a lamb wave resonator, the method comprising:
forming a piezoelectric layer on a substrate so that a first side of the piezoelectric layer is proximal to the substrate and a second side of the piezoelectric layer is distal from the substrate;
forming an interdigital transducer on the second side so that a plurality of first electrode fingers and a plurality of second electrode fingers extending in a first direction are alternately arranged in a second direction that intersects the first direction; and
forming a dielectric layer, located on the second side so that a first part of the dielectric layer is disposed on a surface of the piezoelectric layer and is located on periphery of the first electrode fingers and the second electrode fingers.

35. The method of claim 34, further comprising:
forming, after forming the interdigital transducer, a first dielectric film so that the first dielectric film covers the interdigital transducer and the piezoelectric layer; and
forming a second dielectric film on the first dielectric film so that the second dielectric film is located on a periphery of the first electrode fingers and the second electrode fingers so that the second dielectric film and a portion of the first dielectric film that is located on the surface of the piezoelectric layer define a first part and a portion of the first dielectric film that is located on a surface of the interdigital transducer defines a second part that is thinner than the first part.

36. The method of claim 34, further comprising:
forming the dielectric layer on a side of the piezoelectric layer;
forming, after the interdigital transducer is formed, a third dielectric film on a surface of the interdigital transducer so that the third dielectric film covers the interdigital transducer and the piezoelectric layer; and
thinning a portion of the third dielectric film that is located on the surface of the interdigital transducer, to form a thinned portion so that the thinned portion defines a second part thinner than the first part.

37. The method of claim 35, further comprising forming the first part and the second part so that S1 is greater than S2.

38. The method of claim 37, further comprising forming the first part and the second part so that (S1−S2)≥50 nanometers (nm).

39. The method of claim 35, further comprising:
forming the second part with a first projection on the piezoelectric layer, and
forming the interdigital transducer with a second projection on the piezoelectric layer and enveloping the first projection.
